(19) United States
(12) Patent Application Publication
(10) Pub. No.: US 2025/0096182 A1
(43) Pub. Date: Mar. 20, 2025

(54) POWER MODULES AND PANEL-LEVEL METHODS OF MAKING THE SAME

(71) Applicant: PEP INNOVATION PTE. LTD., Singapore (SG)

(72) Inventors: Hwee Seng CHEW, Singapore (SG); Senthil Kumar MUNIRATHINAM, Singapore (SG)

(21) Appl. No.: 18/960,766

(22) Filed: Nov. 26, 2024

Related U.S. Application Data
(63) Continuation-in-part of application No. 17/508,335, filed on Oct. 22, 2021.
Application No. 17/508,335 is a continuation-in-part of application No. 16/805,853, filed on Mar. 2, 2020, now Pat. No. 11,233,028.
Application No. 16/805,853 is a continuation-in-part of application No. 15/826,268, filed on Nov. 29, 2017, now Pat. No. 11,049,734.

(51) Int. Cl. H01L 23/00; H01L 23/367; H01L 25/065

(52) U.S. Cl. CPC H01L 24/24; H01L 24/19; H01L 24/25; H01L 25/0655; H01L 23/3672; H01L 2224/19; H01L 2224/24137; H01L 2224/245; H01L 2224/2518

(57) ABSTRACT

A power module having a semiconductor package in which all the interconnections are formed by direct copper (Cu). In this way, the power module is suitable for high power efficiency. In addition, the direct copper (Cu) interconnection also enhances heat dissipation of the semiconductor package and thus makes the power module more reliable for operation, particularly under a high temperature. power module further includes a substrate (either a direct bonded copper (DBC) substrate or a ceramic substrate) on which the semiconductor package is mounted on; a plurality of external connecting structures coupled to the substrate for electrically leading out the power module; and at least one signal lead mounted on the substrate.

### CROSS-REFERENCE TO RELATED APPLICATIONS

This application is a continuation-in-part application of U.S. patent application Ser. No. 17/508,335 filed on Oct. 22, 2021 entitled “CHIP PACKAGE METHOD AND CHIP STRUCTURE”, which is a continuation-in-part application of U.S. patent application Ser. No. 16/805,853 filed on Mar. 2, 2020 entitled “CHIP PACKAGING METHOD AND CHIP STRUCTURE”, now U.S. Pat. No. 11,233,028, which is a continuation-in-part application of U.S. patent application Ser. No. 15/826,268 filed on Nov. 29, 2017 entitled “Method of Packaging Chip and Chip Package Structure”, now U.S. Pat. No. 11,049,734, which are incorporated herein by reference in their entities. This application also claims priority to Singapore application Ser. No. 10/202,303517V, filed on Dec. 14, 2023 and entitled “DIRECT Cu INTERCONNECT POWER MODULE FOR POWER INVERTERS”, which is incorporated herein by reference in its entirety.

### TECHNICAL FIELD

The present application relates to a power module; and more particularly relates to a semiconductor package of the power module having direct copper (Cu) interconnections. The present application also relates to panel-level methods of making the semiconductor package and the power module.

Traditional power modules such as power converters use wire bonding for interconnecting multiple components. However, they cannot satisfy the need of high power efficiency (including rapid switching, high frequencies, as well as high voltages and large currents) and heat dissipation. Meanwhile, traditional power modules are not sufficiently robust since wire bonding is easy to break down under a long-time operation.

Therefore, the present application discloses a power module having a special semiconductor package in which all the interconnections are formed by direct copper (Cu). In this way, the power module is suitable for high power efficiency. In addition, the direct copper (Cu) interconnection also enhances heat dissipation of the semiconductor package and thus makes the power module more reliable for operation, particularly under a high temperature. The power module includes various forms of converters, such as an inverter for converting Direct Current (DC) to Alternating Current (AC), a rectifier for converting AC to DC, a chopper for converting DC to DC of different voltages, and an AC regulator for converting AC to AC of different phases.

### SUMMARY

As a first aspect, the present application discloses a semiconductor package for a power module. The semiconductor package includes at least one high-side semiconductor die having a high-side active surface and a high-side inactive surface; at least one low-side semiconductor die having a low-side active surface and a low-side inactive surface; a plurality of vertical structures surrounding the at least one high-side semiconductor die and at least one low-side semiconductor die, wherein each of the vertical structure has a front surface aligned with the high-side active surface and low-side active surface and a back surface aligned with the high-side inactive surface and the low-side inactive surface; a molding layer encapsulating the at least one high-side semiconductor die and at least one low-side semiconductor die and the plurality of vertical structures; a front build-layer coupled to the at least one high-side semiconductor die at the high-side active surface, the at least one low-side semiconductor die at the low-side active surface, and the vertical structure at the front surface; a back build-up layer coupled to the at least one high-side semiconductor die at the high-side inactive surface, the at least one low-side semiconductor die at the low-side inactive surface, and the vertical structure at the back surface; and an external connection layer coupled to the back build-up layer.

As a second aspect, the present application discloses a power module. The power module includes the semiconductor package which further includes the at least one low-side semiconductor die and the at least one high-side semiconductor die as described in the first aspect; a substrate (either a direct bonded copper (DBC) substrate or a ceramic substrate) on which the semiconductor package is mounted on, wherein functional circuitries of the at least one low-side semiconductor die and at least one high-side semiconductor die are led out to the substrate; an external connecting mechanism coupled to the substrate for electrically leading out the power module; and at least one signal lead mounted on the substrate.

As a third aspect, the present application discloses a method of making the power module as described in the second aspect of the present application. The method includes making a semiconductor package configured for the power module, wherein the semiconductor package comprises at least one low-side semiconductor die and at least one high-side semiconductor die; mounting the semiconductor package onto a substrate (either a direct bonded copper (DBC) substrate or a ceramic substrate), wherein functional circuitries of the at least one low-side semiconductor die and at least one high-side semiconductor die are led out to the substrate; coupling an external connecting mechanism to the substrate; and mounting at least one signal lead onto the substrate.

### BRIEF DESCRIPTION OF THE DRAWINGS

The accompanying figures (Figs.) illustrate embodiments and serve to explain principles of the disclosed embodiments. It is to be understood, however, that these figures are presented for purposes of illustration only, and not for defining limits of relevant applications.

FIG. 1 illustrates a flow chart of a panel-level method S100 of making a power module 10 having a semiconductor package 20 according to an exemplary embodiment of the present disclosure.

FIGS. 2 to 6c illustrate Step S102 of the panel-level method S100 for preparing semiconductor dies having a protective layer.

FIGS. 7a & 7b illustrate a first sub-step of Step S104 of the panel-level method S100 for providing a first carrier.

FIGS. 8a to 8j illustrate a second sub-step of Step S104 of the panel-level method S100 for bonding the semiconductor dies (having the protective layer) and vertical structures onto the first carrier.

FIG. 9 illustrates Step S106 of the panel-level method S100.

FIGS. 10a to 10c illustrate Step S108 of the panel-level method S100.

FIGS. 11 to 13 illustrate an optional Step S110 of the panel-level method S100.

FIGS. 14 & 15 illustrate Step S112 of the panel-level method S100.

FIGS. 16 to 21 illustrate Step S114 of the panel-level method S100.

FIG. 22 illustrates Step S116 of the panel-level method S100.

FIGS. 23a to 23d illustrate a first embodiment of Steps S118 & Step S120 of the panel-level method S100.

FIGS. 24a & 24b illustrate an embodiment 260 of the semiconductor package 20 obtained from the panel-level method S100.

FIG. 25 illustrates a second embodiment of Steps S118 & S120 of the panel-level method S100.

FIGS. 26a to 26c illustrate other embodiments 270, 280 and 290 of the semiconductor package 20 obtained from the panel-level method S100.

FIGS. 27a to 27d illustrate other embodiments 300, 310, 320 and 330 of the semiconductor package 20 obtained from the panel-level method S100. illustrate Step S122 of the panel-level method S100. FIGS. 28a to 30b

FIGS. 31a to 32a illustrate an embodiment of Step S124 of the panel-level method S100 and an embodiment 400 of the power module 10.

FIG. 32b illustrates an optional Step S126 of the panel-level method S100 to the embodiment 400 for making another embodiment 410 of the power module 10 accordingly.

FIGS. 33a & 33b illustrate an optional Step S128 of the panel-level method S100 to the embodiment 400 for making an embodiment 420 of the power module 10 accordingly.

FIG. 34 illustrates the optional Step S126 of the panel-level method S100 to the embodiment 420 for making another embodiment 430 of the power module 10 accordingly.

FIGS. 35a & 35b illustrate another optional Step S130 of the panel level method S100 and an embodiment 440 of the power module 10 accordingly.

FIG. 35c illustrates the optional Step S126 of the panel-level method S100 to the embodiment 440 for making another embodiment 450 of the power module 10 accordingly.

FIGS. 36a to 38b illustrates other embodiments 460, 470, 480, 490, 500 and 510 of the power module 10.

FIGS. 39a & 39b illustrates another two embodiments 340, 350 of the semiconductor package 20.

FIGS. 40a 40b illustrates another embodiment of S124 of the panel-level method S100 with the embodiments 340 of the semiconductor package 20 for making an embodiment 520 of the power module 10.

FIGS. 41a & 41b illustrates other embodiments 530, 540 of the power module 10 with a liquid cooling system.

### DETAILED DESCRIPTION

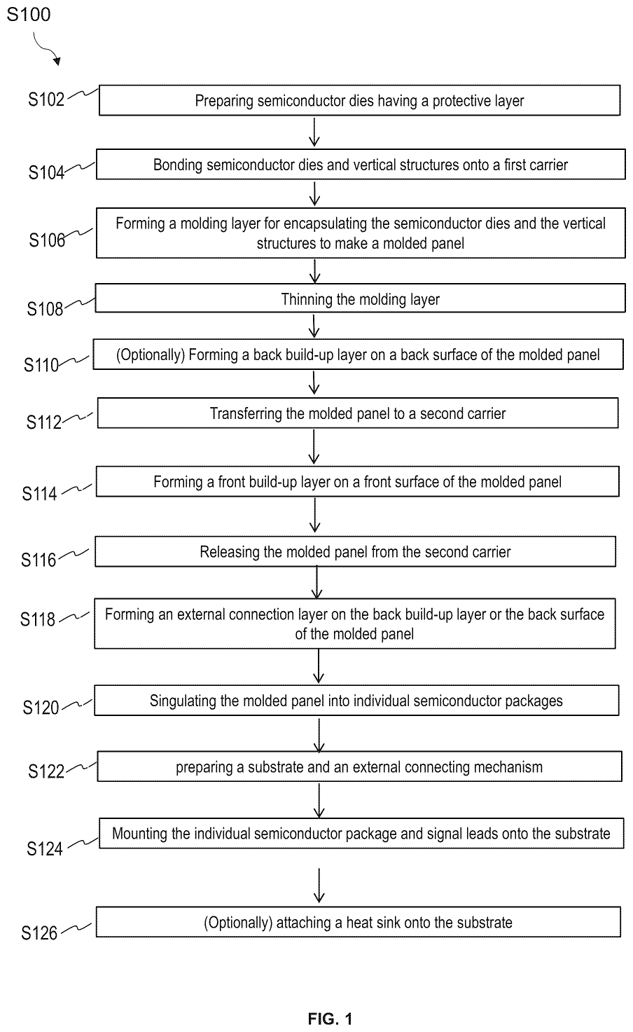

FIG. 1 illustrates a flow chart of a panel-level method S100 of making a power module 10 having a semiconductor package 20 according to an exemplary embodiment of the present disclosure. The panel-level method S100 includes Steps S102 to S124, as well as optional Steps S126, S128 and S130.

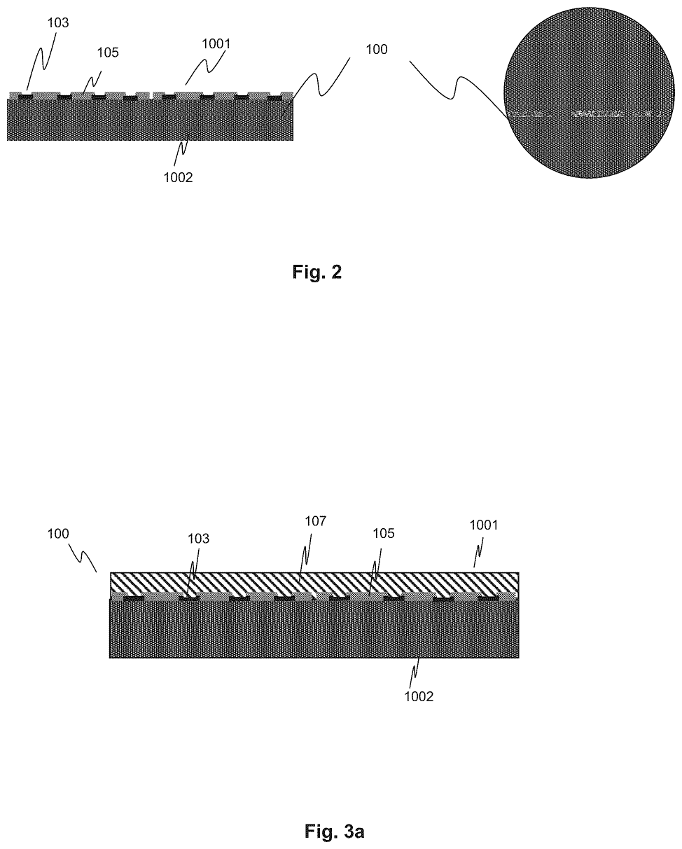

FIGS. 2 to 6c illustrate Step S102 of the panel-level method S100 for preparing semiconductor dies 113 (such as low-side semiconductor dies 202 and high-side semiconductor dies 204 as shown below) having a protective layer 107. As shown in FIG. 2, at least one wafer 100 is provided; the wafer 100 has a wafer active surface 1001 and a wafer back surface 1002; the wafer 100 includes a plurality of dies 113, and active surfaces of the dies 113 constitutes the wafer active surface 1001; the active surface of each die 113 in the wafer 100 forms active components and passive components by using a series of processes such as doping, deposition and etching, etc.; the active components include diodes and triodes, etc.; the passive components include voltage elements, capacitors, resistors and inductors, etc.; and these active components and passive components are connected by connection wires to form a functional circuit, so as to implement various functions. The wafer active surface 1001 further includes an electrical connection pad 103 for leading out the functional circuit and an insulating layer 105 for protecting the electrical connection pad 103.

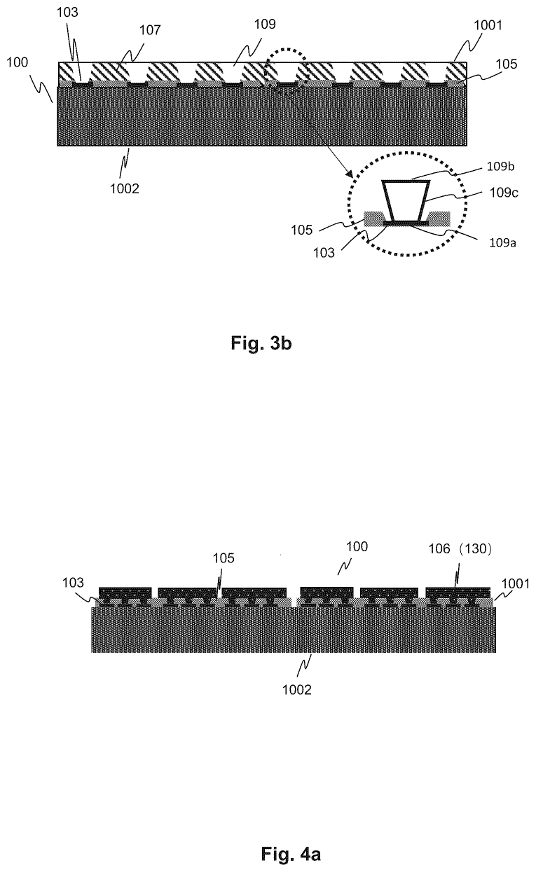

Then, apply the protective layer 107 to the wafer active surface 1001. FIG. 3a to FIG. 3b show an optional process of applying the protective layer 107 to the wafer active surface 1001. As shown in FIG. 3a, the protective layer 107 is applied to the wafer active surface 1001. Preferably, the protective layer 107 is applied to the wafer active surface 1001 by lamination. Optionally, before the step of applying the protective layer 107 to the wafer active surface 1001, the wafer active surface 1001 and/or a surface, which is to be applied to the wafer 100, of the protective layer 107 are physically and/or chemically treated, so that the protective layer 107 and the wafer 100 are bonded together more closely. The treatment optionally is plasma surface treatment to roughen the surface so as to increase a bonding area and/or chemically-promoting modifier treatment of introducing a chemically-promoting modifier group (for example, a surface modifier comprising both a group having affinity with an organic substance and a group having affinity with an inorganic substance) between the wafer 100 and the protective layer 107 so as to increase a bonding force at an interface between the organic layer and the inorganic layer.

As shown in FIG. 3b, a protective layer opening 109 is formed on a surface of the protective layer 107. The protective layer opening 109 is formed in the protective layer 107 at a position corresponding to the electrical connection pad 103 provided on the wafer active surface 1001, to expose the electrical connection pad 103 provided on the wafer active surface 1001. Preferably, the protective layer openings 109 correspond to the electrical connection pads 103 provided on the wafer active surface 1001 in a one-to-one manner. Optionally, each protective layer opening 109 of at least a part of the protective layer openings 109 corresponds to a plurality of electrical connection pads 103. Optionally, at least a part of the electrical connection pads 103 correspond to a plurality of protective layer openings 109. Optionally, at least a part of the protective layer openings 109 have no corresponding electrical connection pads 103, or at least a part of the electrical connection pads 103 have no corresponding protective layer openings 109.

The protective layer opening 109 may be formed by a laser patterning process or a photolithography patterning process. If the protective layer opening 109 is formed by the laser patterning process, preferably, before the protective layer 107 is applied to the wafer active surface 1001, a chemical plating process is performed on the wafer active surface 1001 to form a conductive cover layer on the electrical connection pad 103. Optionally, the conductive cover layer comprises one or more layers of Cu, Ni, Pd, Au, Cr; preferably, the conductive protective layer is a Cu layer; and the conductive cover layer preferably has a thickness of 2 μm to 3 μmm. The conductive cover layer is not shown in the drawings. The conductive cover layer protects the electrical connection pad 103 provided on the wafer active surface 1001 from being damaged by laser in a subsequent step of forming the protective layer opening.

Preferably, as shown by a partially enlarged view in FIG. 3b, a gap is formed between a lower surface 109a of the protective layer opening 109 and the insulating layer 105; preferably, the lower surface 109a of the protective layer opening 109 is located at a position close to a central portion of the electrical connection pad 103.

In a preferred embodiment, the protective layer opening 109 has a shape such that an area of an upper surface 109b of the protective layer opening 109 is larger than an area of the lower surface 109a of the protective layer opening 109, and an area ratio of the lower surface 109a to the upper surface 109b is 60% to 90%. In this case, a side wall 109c of the protective layer opening 109 has a slope which facilitates filling of a conductive material, so that the conductive material is uniformly and continuously formed on the side wall during a filling process.

Optionally, the protective layer opening 109 is not formed in this step, and the protective layer opening 109 is formed in the protective layer for example after a process of peeling off a carrier.

Optionally, a conductive medium is filled in the protective layer opening 109 such that the protective layer opening 109 becomes a conductive filled via. At least one of the conductive filled vias are connected with the electrical connection pads 103 provided on the wafer active surface 1001. In this way, the conductive filled via leads out the electrical connection pad 103 provided on the wafer active surface 1001 unilaterally to the surface of the protective layer 107, and the protective layer 107 is formed around the conductive filled via. The conductive medium for example is made of a material such as gold, silver, copper, tin, aluminum and the like, or a combination thereof, or other suitable conductive materials; the conductive medium is filled in the protective layer opening 109 to form the conductive filled via by physical vapor deposition (PVD), chemical vapor deposition (CVD), sputtering, electrolytic electroplating, electrodeless electroplating, or other suitable metal deposition processes.

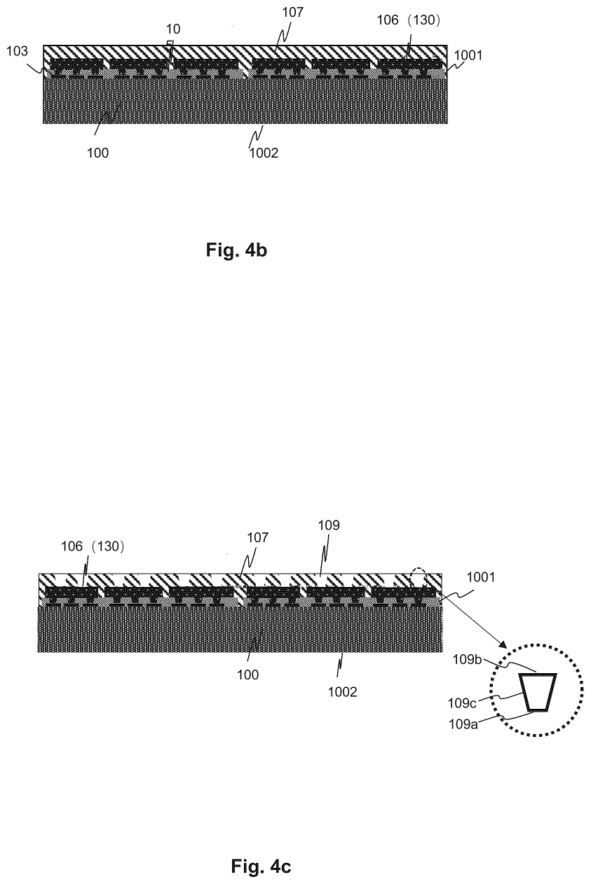

FIG. 4a to FIG. 4c show another optional process of applying the protective layer 107 to the wafer active surface 1001. As shown in FIG. 4a, a wafer conductive layer 130 is formed on the wafer active surface 1001. The wafer conductive layer 130 is a wafer conductive trace 106.

The wafer conductive trace 106 for example is made of a material such as copper, gold, silver, tin, aluminum and the like, or a combination thereof, or other suitable conductive materials by PVD, CVD, sputtering, electrolytic electroplating, electrodeless electroplating, or other suitable metal deposition processes. At least a part of the wafer conductive traces 106 are connected with at least a part of the electrical connection pads 103 provided on the wafer active surface 1001.

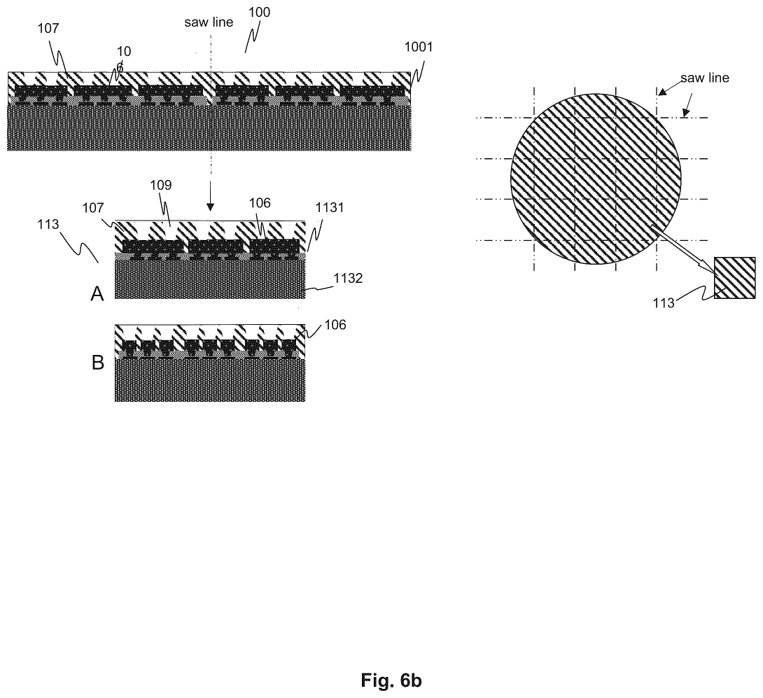

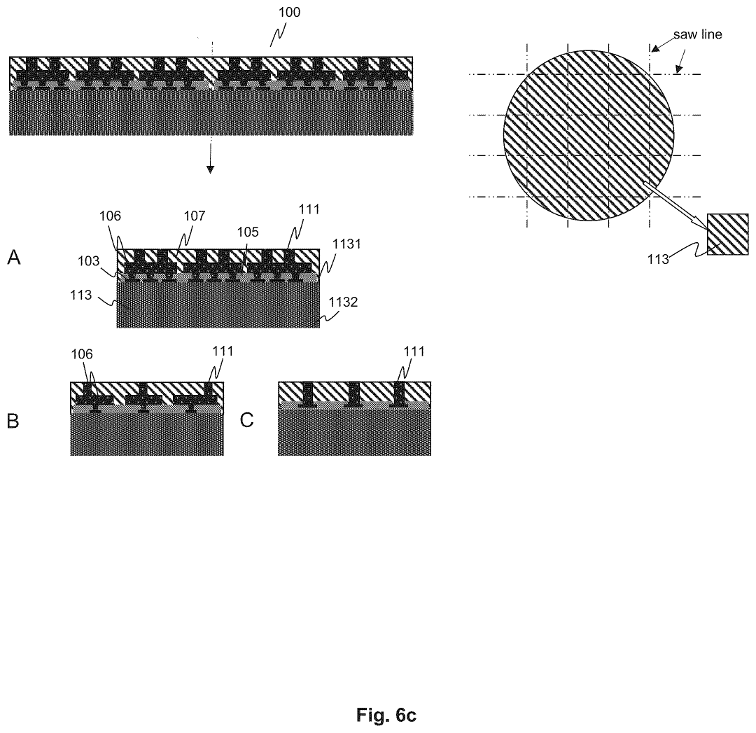

Optionally, the wafer conductive trace 106 interconnects and leads out a plurality of electrical connection pads 103 of at least a part of the electrical connection pads 103 provided on the wafer active surfaces 1001, to obtain the die 113 shown in a die schematic diagram A in FIG. 6b.

Formation of the wafer conductive trace 106 reduces the amount of protective layer openings 109 formed in a subsequent process; and the wafer conductive trace 106 is employed to firstly interconnect the plurality of electrical connection pads 103 according to the circuit design, so that it is not necessary to form the protective layer opening 109 on each electrical connection pad 103. Optionally, the wafer conductive traces 106 respectively lead out at least a part of the electrical connection pads 103 provided on the wafer active surface 1001, to obtain the die 113 shown in a die schematic diagram B in FIG. 6b.

Formation of the wafer conductive trace 106 reduces a difficulty of forming the protective layer opening 109 in a subsequent process; due to the presence of the wafer conductive trace 106, the lower surface 109a of the protective layer opening has a larger area, and accordingly the protective layer opening 109 has a larger area, so that it is possible to form the protective layer opening especially on the wafer 100 having a smaller exposed electrical connection pad 103. Although not shown in the drawings, it should be understood that, a part of the wafer conductive traces 106 respectively lead out a part of the electrical connection pads 103 provided on the wafer active surface 1001, and each of a part of the wafer conductive traces 106 interconnects and leads out a part of the electrical connection pads 103 provided on the wafer active surface 1001.

As shown in FIG. 4b, the protective layer 107 is applied to the wafer active surface 1001 and the wafer conductive layer 130. In one embodiment, the protective layer 107 is applied by lamination. Optionally, before the step of applying the protective layer 107, the wafer active surface 1001 and/or the surface, which is to be applied to the wafer 100, of the protective layer 107 are physically and/or chemically treated, so that the protective layer 107 and the wafer 100 are bonded together more closely. The treatment optionally is plasma surface treatment to roughen the surface so as to increase the bonding area and/or chemically-promoting modifier treatment of introducing the chemically-promoting modifier group (for example, the surface modifier comprising both the group having affinity with the organic substance and the group having affinity with the inorganic substance) between the wafer 100 and the protective layer 107 so as to increase the bonding force at the interface between the organic layer and the inorganic layer.

As shown in FIG. 4c, the protective layer opening 109 is formed on the surface of the protective layer 107. Positions of at least a part of the protective layer openings 109 correspond to the wafer conductive layer 130, and the wafer conductive layer 130 is exposed through the protective layer opening 109; and the protective layer opening 109 has the lower surface 109a and the upper surface 109b. In a preferred embodiment, the protective layer opening 109 has the shape such that the area of the upper surface 109b of the protective layer opening 109 is larger than the area of the lower surface 109a of the protective layer opening 109; in this case, the side wall 109c of the protective layer opening 109 has the slope which facilitates the filling of the conductive material, so that the conductive material is uniformly and continuously formed on the side wall during the filling process.

Preferably, a contact area of a single contact region between the wafer conductive layer 130 and the electrical connection pads 103 is smaller than a contact area of a single contact region between the wafer conductive layer 130 and the protective layer openings 109. In a case that the wafer 100 is designed such that the exposed electrical connection pad 103 has a small area, by forming the conductive layer on the wafer active surface 1001 and then forming the protective layer opening 109, a difficulty in forming the protective layer opening 109 is effectively reduced and a case that the protective layer opening 109 is difficult to form because the lower surface 109a of the protective layer opening is too small is avoided.

The protective layer opening 109 may be formed by the laser patterning process or the photolithography patterning. Optionally, the protective layer opening 109 is not formed in this step, and the protective layer opening 109 is formed in the protective layer for example after the process of peeling off the carrier. Optionally, the conductive medium is filled in the protective layer opening 109 such that the protective layer opening 109 becomes the conductive filled via; at least one of the conductive filled vias are connected with the wafer conductive layer 130; and the protective layer 107 surrounds the conductive filled via.

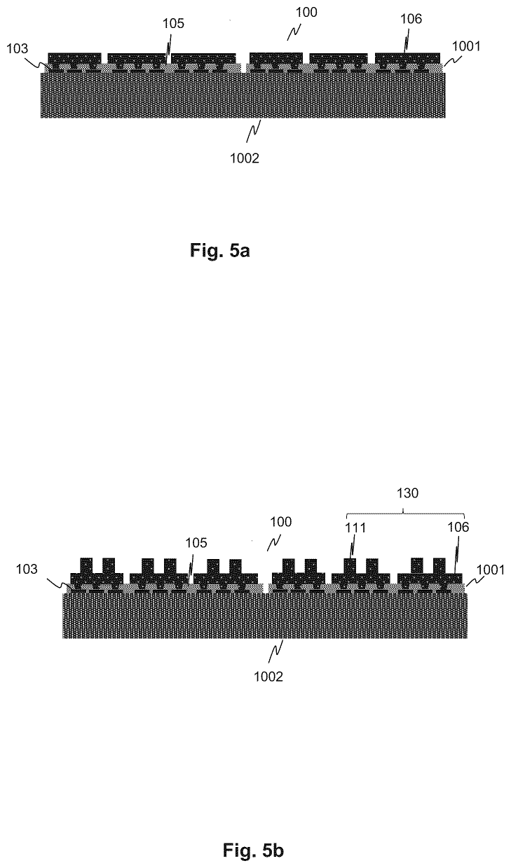

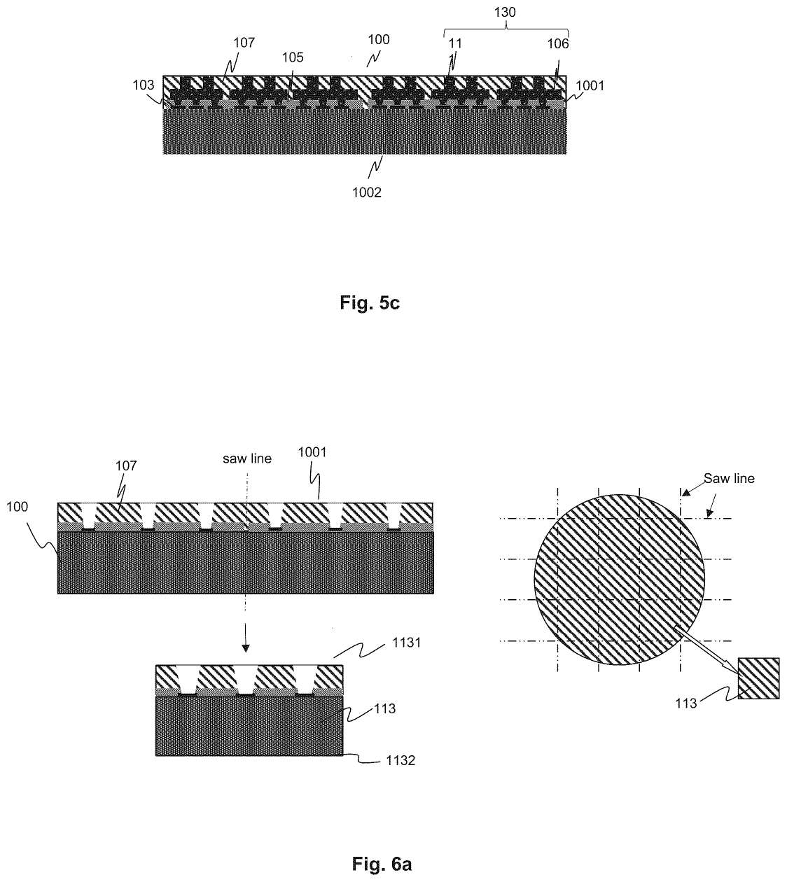

FIG. 5a to FIG. 5c show still another optional process of applying the protective layer 107 to the wafer active surface 1001. As shown in FIG. 5a, the wafer conductive trace 106 is formed on the wafer active surface 1001. The wafer conductive trace 106 for example is made of the material such as copper, gold, silver, tin, aluminum and the like, or a combination thereof, or other suitable conductive materials by PVD, CVD, sputtering, electrolytic electroplating, electrodeless electroplating, or other suitable metal deposition processes. Each of at least a part of the wafer conductive traces 106 interconnects and leads out a plurality of electrical connection pads 103 of at least a part of the electrical connection pads 103. At least a part of the wafer conductive traces 106 respectively lead out at least a part of the electrical connection pads 103, to obtain the die shown in a die schematic diagram B in FIG. 6c.

As shown in FIG. 5b, a wafer conductive stud 111 is formed on a pad or a connection point of the wafer conductive trace 106. The wafer conductive stud 111 for example has a shape of a circle, or may have other shape such as an ellipse, a square, a line and the like. The wafer conductive stud 111 for example is formed of one or more layers of a material such as copper, gold, silver, tin, aluminum and the like, or a combination thereof, or other suitable conductive material by PVD, CVD, sputtering, electrolytic electroplating, electrodeless electroplating, or other suitable metal deposition process. Optionally, the wafer conductive stud 111 is directly formed on the electrical connection pad 103 provided on the wafer active surface 1001 and leads out the electrical connection pad 103, to obtain the die shown in a die schematic diagram C in FIG. 6c.

The wafer conductive trace 106 and/or the wafer conductive stud 111 are collectively referred to as the wafer conductive layer 130. As shown in FIG. 5c, the protective layer 107 is applied to the wafer conductive layer 130. The protective layer 107 is applied onto the wafer conductive layer 130 to cover the wafer conductive layer 130. In one embodiment, the protective layer 107 is applied by lamination. In one embodiment, the protective layer 107 is applied so that the protective layer 107 completely covers the wafer conductive layer 130, in this case, the protective layer 107 is thinned to expose a surface of the wafer conductive layer after the application process of the protective layer 107. In another embodiment, the protective layer 107 is applied to have a thickness such that a surface of the wafer conductive layer 130 is just exposed.

Optionally, before the step of applying the protective layer 107, the wafer active surface 1001 formed with the wafer conductive layer 130 and/or the surface, which is to be applied to the wafer 100, of the protective layer 107 are physically and/or chemically treated, so that the protective layer 107 and the wafer 100 are bonded together more closely. The treatment optionally is plasma surface treatment to roughen the surface so as to increase the bonding area and/or chemically-promoting modifier treatment of introducing the chemically-promoting modifier group (for example, the surface modifier comprising both the group having affinity with the organic substance and the group having affinity with the inorganic substance) between the wafer 100 and the protective layer 107 so as to increase the bonding force at the interface between the organic layer and the inorganic layer.

The protective layer 107 is applied to the wafer active surface 1001 for preventing a permeation of a molding material so as to protect a die active surface 1131 of the die from being damaged during a molding process; meanwhile, during the molding process, a molding pressure is not easy to cause a position shift of the die 113 on a carrier (such as a first carrier 102); in addition, an alignment accuracy requirement of a subsequent process of forming a panel-level conductive layer is lowered.

The protective layer 107 is made of an insulating material, optionally, for example, benzocyclobutene (BCB), polyimide (PI), polybenzoxazole (PBO), polymer-based dielectric film, organic polymer film, or is made of other material having similar insulation and structural properties, by lamination, coating and printing, etc.

Preferably, the protective layer 107 has a Young's modulus in a range of 1,000 MPa to 20,000 MPa; more preferably, the protective layer 107 has a Young's modulus in a range of 1,000 MPa to 10,000 MPa; further preferably, the protective layer 107 has a Young's modulus in a range of 1,000 MPa to 7,000 MPa, 4,000 MPa to 7,000 MPa, or 4,000 MPa to 8,000 MPa; and in a most preferred embodiment, the protective layer 107 has a Young's modulus of 5,500 MPa.

Preferably, the protective layer 107 has a thickness in a range of 15 μm to 50 μm; more preferably, the protective layer 107 has a thickness in a range of 20 μm to 50 μmm; in a preferred embodiment, the protective layer 107 has a thickness of 35 μmm; in another preferred embodiment, the protective layer 107 has a thickness of 45 μm; and in still another preferred embodiment, the protective layer 107 has a thickness of 50 μm.

The protective layer 107 has the Young's modulus in the range of 1,000 MPa to 20,000 MPa; on one hand, the protective layer 107 is soft and has good flexibility and elasticity; on the other hand, the protective layer provides sufficient supporting force so that the protective layer 107 provides sufficient support for a conductive layer formed on the surface of the protective layer 107. Meanwhile, the protective layer 107 has the thickness in the range of 15 μm to 50 μm, it is ensured that the protective layer 107 provides sufficient buffering and support.

Particularly, in some types of chips, it is required not only that a thin die is packaged, but also that the conductive layer has a certain thickness suitable for a large electric flux; at this time, it is selected that the protective layer 107 has the thickness in the range of 15 μm to 50 μm and has the Young's modulus in the range of 1,000 MPa to 10,000 MPa. The soft and flexible protective layer 107 forms a buffer layer between the die 113 and the conductive layer formed on the surface of the protective layer, so that the conductive layer on the surface of the protective layer does not excessively press the die 113 and the die 113 is prevented from being broken under pressure of the thick and heavy conductive layer during the chip is used. Meanwhile, the protective layer 107 has a sufficient strength, so that the protective layer 107 provides sufficient support for the thick and heavy conductive layer.

In the case that the protective layer 107 has the Young's modulus in the range of 1,000 MPa to 20,000 MPa, especially in the case that the protective layer 107 has the Young's modulus in the range of 4,000 MPa to 8,000 MPa and has the thickness in the range of 20 μmm to 50 μm, due to material properties of the protective layer 107, the protective layer 107 effectively protects the die against a pressure from a pin of a die bonder machine during a subsequent process of transferring the die.

The die transferring process is a reconstruction process of arranging and adhering the die 113 which has underwent the cutting and separating process onto the carrier 117; the die transferring process adopts the die bonder machine; the die bonder machine includes the pin; the die 113 on the wafer 100 is jacked up by the pin, and the die 113 which is jacked up is sucked by a bonder head, and then is transferred and bonded to the carrier 117.

During the process that the pin jacks up the die 113, the die 113, especially the thin die 113, is brittle and is easily broken under the jacking pressure of the pin, so the protective layer 107 having the above material properties protects the brittle die 113 to maintain integrity of the die 113 even under a relatively large jacking pressure.

Preferably, the protective layer 107 is an organic/inorganic composite material layer including filler particles. For example, the filler particles are inorganic oxide particles. For example, the filler particles are SiO₂ particles. In one embodiment, the filler particles in the protective layer 107 are two or more different types of inorganic oxide particles, for example, SiO₂ particles and TiO₂ particles mixed with each other. Preferably, the filler particles in the protective layer 107 such as the inorganic oxide particles, e.g., SiO₂ particles, e.g., SiO₂ particles and TiO₂ particles mixed with each other, are spherical or spheroidal. In a preferred embodiment, the filler particles in the protective layer 107 such as the inorganic oxide particles, e.g., SiO₂ particles, e.g., SiO₂ particles and TiO₂ particles mixed with each other, have a fill amount of 50% or more.

An organic material has advantages of easy operation and easy application, and the die 113 to be packaged is made of an inorganic material such as silicon or silicon carbide; if the protective layer 107 is only made of the organic material, a difference between material properties of the organic material and material properties of the inorganic material may increase a difficulty in the packaging process and affect a packaging effect. By employing the organic/inorganic composite material in which the inorganic particles are added to the organic material, the material properties of the organic material is modified, so that the material of the protective layer 107 has properties of both the organic material and the inorganic material.

Especially with respect to a coefficient of thermal expansion (CTE), the silicon die 113 has a relatively low coefficient of thermal expansion, usually about 3 ppm/K, and the protective layer 107 is the organic/inorganic composite material layer including the filler particles to reduce the coefficient of thermal expansion of the protective layer, so that a difference in properties between the organic layer and the inorganic layer in the package structure is reduced.

In a preferred embodiment, in the case that T<Tg, the protective layer 107 has a coefficient of thermal expansion in a range of 3 ppm/K to 10 ppm/K; in a preferred embodiment, the protective layer 107 has a coefficient of thermal expansion of 5 ppm/K; in a preferred embodiment, the protective layer 107 has a coefficient of thermal expansion of 7 ppm/K; and in a preferred embodiment, the protective layer 107 has a coefficient of thermal expansion of 10 ppm/K.

In a subsequent molding process, the die 113 applied with the protective layer 107 expands and contracts correspondingly during heating and cooling processes of the molding process; in the case that the protective layer 107 has the coefficient of thermal expansion in the range of 3 ppm/K to 10 ppm/K, the protective layer 107 and the die 113 maintain a relatively uniform degree of expansion and contraction, so that an interface stress is not easily caused at a bonding interface between the protective layer 107 and the die 113, and thus the bonding between the protective layer 107 and the die 113 is not easily destroyed and the packaged chip is more stable.

The chip after being packaged often needs to undergo a thermal cycle during being used; in the case that the protective layer 107 has the coefficient of thermal expansion in the range of 3 ppm/K to 10 ppm/K, which is the same as or similar to the coefficient of thermal expansion of the die 113, the protective layer 107 and the die 113 maintain a relatively uniform degree of expansion and contraction in the thermal cycle, so that accumulation of interface fatigue at the interface between the protective layer 107 and the die 113 is avoided, and thus the packaged chip becomes more durable and a service life of the packaged chip is prolonged.

On the other hand, if the coefficient of thermal expansion of the protective layer 107 is further reduced, the composite material of the protective layer 107 has to be filled with too many filler particles and the Young's modulus of the material is increased while the coefficient of thermal expansion is further reduced, so that the flexibility of the protective layer is reduced, resulting in excessively strong rigidity but a poor buffering effect of the protective layer 107. It is most preferable to limit the coefficient of thermal expansion of the protective layer to be 5 ppm/k to 10 ppm/k.

In the case that the protective layer opening is formed by laser patterning process, the filler particles in the protective layer 107 (for example, the inorganic oxide particles, such as SiO₂ particles) preferably have a diameter of less than 3 μm; preferably, the filler particles in the protective layer 107 (for example, the inorganic oxide particles, such as SiO₂ particles) have a diameter between 1 μm and 2 μm.

Controlling the diameter of the filler particles to be less than 3 μm facilitates the protective layer opening formed in the protective layer 107 by the laser patterning process to have a smoother side wall, so that the conductive material is sufficiently filled in the conductive material filling process, to avoid a case that, due to a side wall 109c of the protective layer opening 109 having large-sized unevenness, the protective layer opening cannot be filled by the conductive material at a lower side of the side wall that is shielded by a protrusion, and further avoid a case that a conductive property of the conductive filled via is adversely affected.

Meanwhile, by controlling the diameter of the filler particles to be 1 μm to 2 μm, the filler particles with such small diameter will be exposed during the laser patterning process, so that the side wall 109c of the protective layer opening 109 has a certain roughness; in this case, the side wall having a certain roughness and the conductive material have a larger contact area therebetween and thus contact each other more closely, so as to form the conductive filled via with better conductivity.

The above-described diameter of the filler particles is an average value of the diameters of the filler particles. Optionally, the protective layer 107 has a tensile strength in a range of 20 MPa to 50 MPa; and in a preferred embodiment, the protective layer 107 has a tensile strength of 37MPa. Optionally, after the process of applying the protective layer 107 to the wafer active surface 1001, the wafer back surface 1002 is ground to thin the wafer 100 to a desired thickness.

Modern electronic devices are small and lightweight, and thus the chip has a tendency of becoming thinner; in the step, the wafer 100 sometimes needs to be thinned to a very small thickness. However, it is very difficult to process and transfer the thin wafer 100, and a process of grinding and thinning the thin wafer 100 is also difficult, so it is usually difficult to thin the wafer 100 to a desired thickness. In the case that the surface of the wafer 100 has the protective layer 107, the protective layer 107 having the above material properties supports the wafer 100, so that the difficulties in processing, transferring and thinning the wafer 100 are reduced.

Subsequently, cut the wafer 100 applied with the protective layer 107 to form the die 113 having the protective layer 107. As shown in FIG. 6a, the wafer 100 applied with the protective layer 107 is cut along a cutting line, to obtain a plurality of dies 113 formed with the protective layer; and the die 113 has the die active surface 1131 and a die back surface 1132.

As shown in FIG. 6b, the wafer 100 formed with the wafer conductive layer 130, applied with the protective layer 107 and formed with the protective layer opening 109 is cut along the cutting line, to obtain a plurality of dies 113; and the die 113 has the die active surface 1131 and the die back surface 1132.

As shown in the die schematic diagram A in FIG. 6b, the wafer conductive trace 106 interconnects and leads out a plurality of electrical connection pads 103 provided on the die active surface 1131. As shown in the die schematic diagram B in FIG. 6b, the wafer conductive traces 106 respectively lead out the electrical connection pads 103 provided on the die active surface 1131.

As shown in FIG. 6c, the wafer 100 formed with the wafer conductive layer 130 and applied with the protective layer 107 is cut along the cutting line, to obtain a plurality of dies 113; and the die 113 has the die active surface 1131 and the die back surface 1132. As shown in the die schematic diagram A in FIG. 6c, the wafer conductive trace 106 interconnects and leads out a plurality of electrical connection pads 103 provided on the die active surface 1131. As shown in the die schematic diagram B in FIG. 6c, the wafer conductive traces 106 respectively lead out the electrical connection pads 103 provided on the die active surface 1131. As shown in the die schematic diagram C in FIG. 6c, the wafer conductive stud 111 is directly formed at the electrical connection pad 103 provided on the wafer active surface 1001, and leads out the electrical connection pad 103.

Optionally, before the step of cutting the wafer 100 to separate out the dies 113, the method further comprises: performing plasma surface treatment on the surface, applied with the protective layer 107, of the wafer 100 to increase surface roughness, so that adhesiveness of the die 113 to the carrier 117 in a subsequent process is increased and thus position shift of the die under the package pressure is less likely to occur. Due to the material properties of the protective layer, the die 113 which is separated out in the process of cutting the wafer 100 has no burrs and chippings. It should be understood that, if the process permits, the wafer conductive layer 130 and/or the protective layer 107 for example are/is formed on the die active surface 1131 of each die 113 after the wafer 100 is cut into the dies 113 to be packaged according to specific practical situations. The wafer conductive layer 130 refers to a conductive layer formed before the die 113 obtained by cutting the wafer 100 is adhered to the carrier.

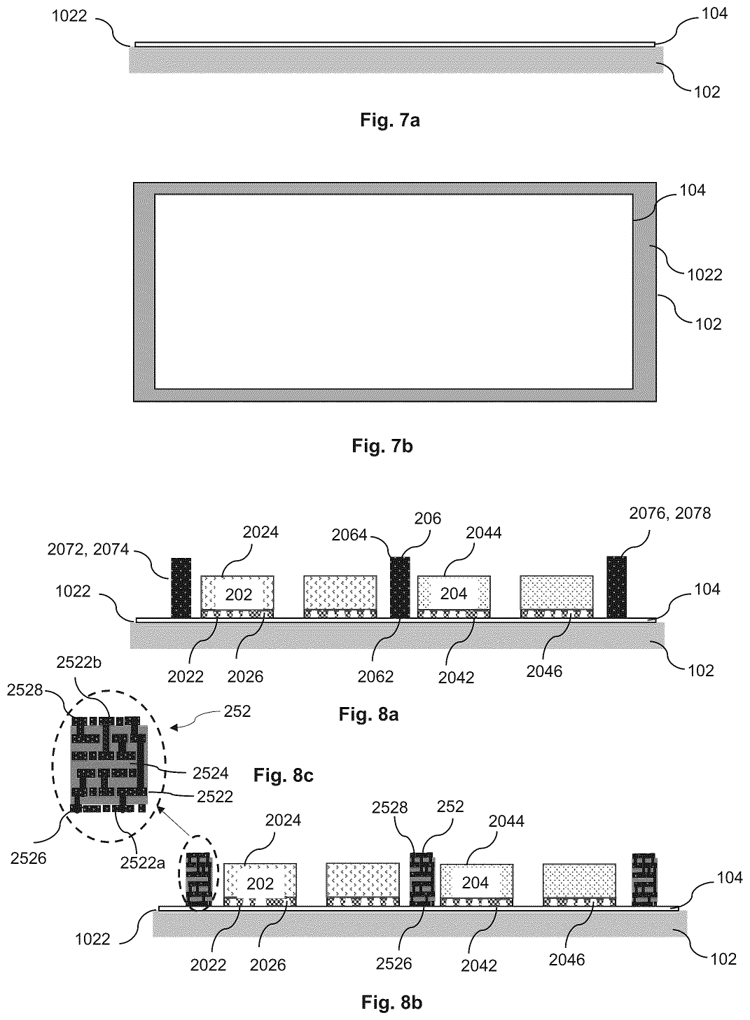

FIGS. 7a & 7b illustrates Step S102 of the panel-level method S100, i.e., providing the first carrier 102 and maybe a first heat and release tape 104. FIG. 7a shows a cross-sectional view of a portion of the first carrier 102 and accordingly a portion of the first heat and release tape 104 secured on the portion of the first carrier 102. FIG. 7b shows a top view of the portion of the first carrier 102 having a rectangular shape. Thus, the first carrier 102 has a plurality of the portions as shown in FIG. 7b. As an embodiment, the first carrier 102 as a whole has a square shape with a size of 700 mm×700 mm which is much larger than traditional wafers with typical diameters of 8 inches or 12 inches. Therefore, the panel-level method S100 has a much greater productivity than traditional wafer-level methods. It is understood that the first carrier 102 may have other shapes, such as rectangular or around shapes. The first heat and release tape 104 may cover a front carrier surface 1022 of the first carrier 102 almost completely for enhancing productivity.

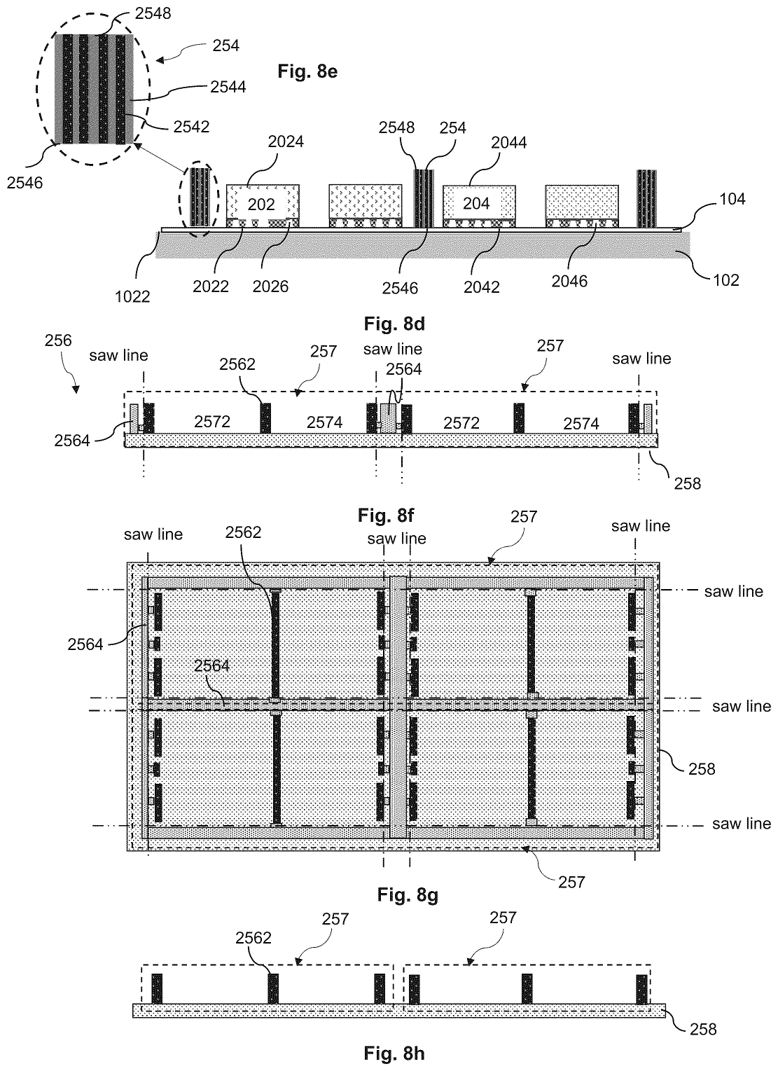

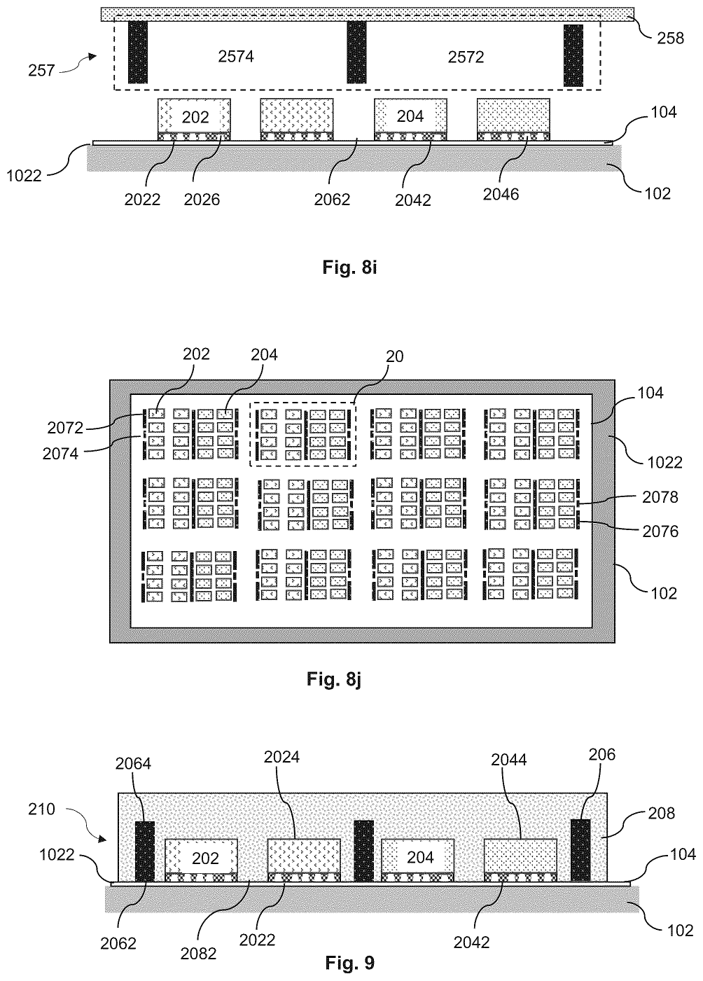

FIGS. 8a to 8f illustrate Step S104 of the panel-level method S100, i.e., bonding semiconductor dies and vertical structures onto the first carrier 102 and the first heat and release tape 104. The first heat and release tape 104 has sufficient adhesivity at an ambient temperature to secure the semiconductor dies and the vertical structures in place on the first carrier 102. FIG. 8a shows a cross-sectional view that the die 113 may include multiple low-side semiconductor dies 202 and multiple high-side semiconductor dies 204 which have all the features and characteristics described above such as the protective layer 107 and the protective layer openings 109 accordingly. The low-side semiconductor dies 202 and the high-side semiconductor dies 204 are bonded onto the first carrier 102 and first heat and release tape 104 at their respective pre-determined positions. The terms “low-side” and “high-side” refer to a higher electrical voltage and a lower electrical voltage respectively; and therefore, the low-side semiconductor die 202 and the high-side semiconductor die 204 would be electrically coupled to a terminal (either input or output) of the lower electrical voltage and another terminal (either input or output) of the higher electrical voltage of a power module respectively. The low-side semiconductor die 202 and the high-side semiconductor die 204 may be metal-oxide-semiconductor field-effect transistor (MOSFET) made of silicon (Si), silicon carbide (SiC) or gallium nitride (GaN). In particular, the low-side semiconductor die 202 and the high-side semiconductor die 204 are bonded in a face-down manner, i.e., a low-side active surface 2022 of the low-side semiconductor die 202 and a high-side active surface 2042 of the high-side semiconductor die 204 are in contact with the first heat and release tape 104 and the front carrier surface 1022 of the first carrier 102. The low-side semiconductor die 202 and the high-side semiconductor die 204 have a low-side inactive surface 2024 and a high-side inactive surface 2044 opposed to the low-side active surface 2022 and the high-side active surface 2042 respectively. The low-side semiconductor die 202 and the high-side semiconductor die 204 may be configured to have a same die thickness so that the low-side active surface 2022 and the low-side inactive surface 2024 of the low-side semiconductor die 202 are co-planar with the high-side active surface 2042 and the high-side inactive surface 2044 of the high-side semiconductor die 204 respectively.

The low-side semiconductor die 202 and the high-side semiconductor die 204 have low-side pre-vias 2026 and high-side pre-vias 2046 at the low-side active surface 2022 and the high-side active surface 2042 respectively. The low-side pre-vias 2026 and the high-side pre-vias 2046 can be filled with conductive materials such as copper (Cu) or titanium/copper (Ti/Cu) composites and then turned into low-side filled vias 2028 of the low-side semiconductor die 202 and high-side filled vias 2048 of the high-side semiconductor die 204 respectively. Therefore, functional circuitries of the low-side semiconductor die 202 and the high-side semiconductor die 204 can be led out from contact pads at the low-side active surface 2022 of the low-side semiconductor die 202 and the high-side active surface 2042 of the high-side semiconductor die 204 by the low-side filled vias 2028 and the high-side filled vias 2048 respectively.

The low-side semiconductor die 202 and the high-side semiconductor die 204 may be singulated from an incoming low-side semiconductor wafer (not shown) and an incoming high-side semiconductor wafer (not shown) respectively. The incoming low-side semiconductor wafer and the incoming high-side semiconductor wafer have their functional circuitries at their respective active wafer surfaces. They may be made of silicon (Si) wafers, silicon carbide (SiC) wafers or gallium nitride (GaN) wafers; and their inactive wafer surfaces are made of the same semiconductor materials. Accordingly, after singulation the active wafer surfaces of the incoming low-side semiconductor wafer and the incoming high-side semiconductor wafer form the low-side active surface 2022 and the high-side active surface 2042 respectively with the functional circuitries of the low-side semiconductor die 202 and the high-side semiconductor die 204 thereon; while the inactive wafer surfaces of the incoming low-side semiconductor wafer and the incoming high-side semiconductor wafer form the low-side inactive surface 2024 and the high-side inactive surface 2044 respectively. In addition, the incoming low-side semiconductor wafer and the incoming high-side semiconductor wafer may have conductive layers on their inactive wafer surfaces respectively. Then, after the singulation, the conductive layers are retained at the low-side inactive surface 2024 and the high-side inactive surface 2044 respectively. The conductive layers would function as an external connection layer 248 in subsequent processes.

The vertical structures may take various forms. The vertical structures may be firstly prepared into individual pieces and then bonded onto the first carrier 102 and the first heat and release tape 104. Alternatively, the vertical structures may be bonded in a gang manner, i.e., multiple vertical structures are bonded onto the first carrier 102 and the first heat and release tape 104 as a whole in a single process. As an embodiment shown in FIG. 8a, the vertical structures may include multiple copper (Cu) columns 206 as an example of the vertical structures firstly prepared into individual pieces and then bonded around the low-side semiconductor die 202 and the high-side semiconductor die 204 on the first carrier 102 and the first heat and release tape 104. The copper (Cu) column 206 has a front surface 2062 aligned with the low-side active surface 2022/the high-side active surface 2042 and a back surface 2064 aligned with the low-side inactive surface 2024/the high-side inactive surface 2044. In particular, the front surface 2062 of the copper (Cu) column 206 is in contact with the first heat and release tape 104 and the front carrier surface 1022 of the first carrier 102. Therefore, the front surface 2062 of the copper (Cu) column 206 is co-planar with the low-side active surface 2022 of the low-side semiconductor die 202 and the high-side active surface 2042 of the high-side semiconductor die 204. Meanwhile, the copper (Cu) column 206 has a column height (measured between the front surface 2062 and the back surface 2064) greater than the die thickness of the low-side semiconductor die 202 and the high-side semiconductor die 204. In an embodiment, for each of the semiconductor package 20, the copper (Cu) column 206 includes two first copper columns 2072 arranged on the low-side, and one second copper column 2074 arranged between the two first copper columns 2072 in a direction vertical to the cross-sectional view in FIG. 8a. Similarly, the copper (Cu) column 206 also includes two third copper columns 2076 on the high-side, and one fourth copper column 2078 arranged between the two third copper columns 2076 in the direction vertical to the cross-sectional view in FIG. 8a.

As another embodiment shown in FIG. 8b, the vertical structures may include multiple Molded Interconnect substrates (MIS) units 252 as another example of the vertical structures firstly prepared into individual pieces and then bonded around the low-side semiconductor die 202 and the high-side semiconductor die 204. FIG. 8c shows an enlarged view of the MIS units 252. Each MIS unit 252 further includes multiple routing layers 2522 interconnected for electrical conduction; and an insulating portion 2524 for insulating the routing layers 2522 within the MIS unit 252. The routing layer 2522 may be made of any conducting materials, such as copper (Cu). Compared with the copper (Cu) column 206, the MIS unit 252 consumes less copper and therefore makes the semiconductor package 20 lighter in weight. Similarly, the MIS unit 252 has a MIS front surface 2526 co-planar with the low-side active surface 2022 of the low-side semiconductor die 202 and the high-side active surface 2042 of the high-side semiconductor die 204. The MIS unit 252 has a MIS height (measured between the MIS front surface 2526 and a MIS back surface 2528 of the MIS unit 252) greater than the die thickness of the low-side semiconductor die 202 and the high-side semiconductor die 204. FIG. 8c also shows that the routing layers 2522 of the MIS unit 252 has a first routing layer 2522a and a second routing layer 2522b at the MIS front surface 2526 and the MIS back surface 2528, respectively. The first routing layer 2522a and the second routing layer 2522b are exposed from the insulating portion 2524 of the MIS unit 252.

As another embodiment shown in FIG. 8d, the vertical structures may include multiple Molded Via substrate (MVS) units 254 as another example of the vertical structures which are firstly prepared into individual pieces and then bonded around the low-side semiconductor die 202 and the high-side semiconductor die 204. FIG. 8e shows an enlarged view of the MVS unit 254. Each MVS unit 254 further includes multiple conductive through-vias 2542 for electrical conduction; and an insulating portion 2544 for insulating the conductive through-vias 2542 within the MVS unit 254. The conductive through-vias 2542 may be made of any conducting materials, such as copper (Cu). Similar to the MIS unit 252, the MVS unit 254 consumes less copper and therefore makes the semiconductor package 20 lighter in weight. It also shows that the MVS unit 254 has a MVS front surface 2546 co-planar with the low-side active surface 2022 of the low-side semiconductor die 202 and the high-side active surface 2042 of the high-side semiconductor die 204. The MVS unit 254 has a MVS height (measured between the MVS front surface 2546 and a MVS back surface 2548 of the MVS unit 254) greater than the die thickness of the low-side semiconductor die 202 and the high-side semiconductor die 204. The MIS unit 252 and the MVS unit 254 have the same function as the copper (Cu) column 206, and subsequent processes would be only described using the copper (Cu) column 206 for simply illustration. But it is understood that all the subsequent processes would be also appliable to the MIS unit 252 and the MVS unit 254.

As another embodiment shown in FIGS. 8f to 8i, the vertical structure may include a metal frame 256 as another example of the vertical structures which are bonded in the gang manner. FIGS. 8f & 8g respectively shows a cross-sectional view and a top view that the metal frame 256 comprises an array of metal units 257, such as 2 metal units 257 as indicated by the dashed rectangles in FIGS. 8f to 8i. The metal frame 256 for example is an existing lead frame in the industry, or is formed by etching or mechanical stamping one sheet or one block of metal piece according to actual needs. The metal piece to be patterned for example is made of a single metal such as copper, or an alloy. A surface of the metal piece for example is partially or completely coated with a second metal such as nickel and/or gold, to protect the metal piece from environmental erosion such as oxidation. In some embodiments, a thickness of the metal piece is not less than the die thickness of the semiconductor dies 202, 204. As shown in FIG. 8g, the metal piece is patterned to include 2 identical metal units 257 and each of the metal units 257 has a rectangular outer contour; however, such design is exemplary, the amount of the metal units 257 is not limited to 2 and may be set according to actual needs, and the metal unit 257 may have a shape of a rectangle, or other shape.

The metal frame 256 includes multiple connection pads 2562 arranged on an inner side of an outer contour edge of the metal frame 256, or are arranged at other positions according to actual needs; and the connection pads 2562 are connected by connection bars 2564 made of the metal that is not etched away from the metal piece. The connection bar 2564 is reserved during the metal piece and patterned to ensure that the connection pads 2562 and some other features formed by patterning of the metal piece are connected with the outer contour edge of the metal frame 256, so that it is ensured that the features patterned on the metal frame 256 will not deform or even fall during transferring the metal frame 256. Preferably, the metal piece is firstly affixed onto a temporary support 258 for patterning, and after the patterning is completed, the metal frame 256 is transferred by means of the temporary support 258 onto the first carrier 102 and the first heat and release tape 104. However, it is understood that the connection pads 2562 may be individually bonded onto the temporary support 258; and accordingly, it is not necessary to form the connection bar 2562 to the metal piece during its etching or mechanical stamping.

The metal frame 256 includes multiple vacancies, including a first vacancy 2572 and a second vacancy 2574 for accommodating the high-side semiconductor dies 204 and the low-side semiconductor dies 202 respectively in a subsequent process (as shown in FIG. 8i). Then, FIG. 8h shows a cross-sectional view that the connection bar 2564 are removed on the temporary support 258 along saw lines, leaving the connection pads 2562 individually separated but secured in place on the temporary support 258.

FIG. 8i shows a cross-sectional view that the metal units 257 on the temporary support 258 are flipped and face to the first carrier 102 and the first heat and release tape 104. In particular, the metal units 257 are precisely placed in relation to the high-side semiconductor dies 204 and the low-side semiconductor dies 202 respectively, so that the first vacancy 2572 and the second vacancy 2574 of each of the metal units 257 are aligned thereto for the accommodation as described above. Although only one metal unit 257 is shown in FIG. 8i, it is understood that all the metal units 257 on the temporary support 258 are flipped and bonded onto the first carrier 102 and the first heat and release tape 104 as a whole in the gang manner.

FIG. 8j shows a top view that the low-side semiconductor dies 202 and the high-side semiconductor dies 204 are arranged according to a design of the semiconductor package 20 as shown in a dash rectangle. As an embodiment, the semiconductor package 20 has 8 low-side semiconductor dies 202 grouped on a left side in FIG. 8f (low-side) and 8 high-side semiconductor dies 204 grouped on a right side in FIG. 8f (high-side). It is understood that the design may vary to have other numbers of the low-side semiconductor die 202 and/or the high-side semiconductor die 204. There are 12 semiconductor packages 200 arranged in a matrix of 3 rows and 4 columns on the portion of the first carrier 102 and the first heat and release tape 104 as shown in FIG. 8f, but it is understood that much more semiconductor packages 200 (such as several hundreds or even thousands) could be bonded on the whole of the first carrier 102 and the first heat and release tape 104 for performing subsequent processes simultaneously in order to enhance productivity.

FIG. 9 illustrates Step S106 of the panel-level method S100, i.e., forming the molding layer 208 for encapsulating the low-side semiconductor die 202, the high-side semiconductor die 204 and the copper (Cu) column 206 to make a molded panel 210. The low-side inactive surface 2024 of the low-side semiconductor die 202, the high-side inactive surface 2044 of the high-side semiconductor die 204 and the back surface 2064 of the copper (Cu) column 206 are completely encapsulated inside the molding layer 208; while the low-side active surface 2022 of the low-side semiconductor die 202, the high-side active surface 2042 of the high-side semiconductor die 204 and the front surface 2062 of the copper (Cu) column 206 are not encapsulated due to their contact with the first heat and release tape 104 and the front carrier surface 1022 of the first carrier 102. In particular, the molding layer 208 has a first molding surface 2082 in contact with the first heat and release tape 104 and the front carrier surface 1022 of the first carrier 102 so that the first molding surface 2082 is co-planar with the low-side active surface 2022 of the low-side semiconductor die 202, the high-side active surface 2042 of the high-side semiconductor die 204 and the front surface 2062 of the copper (Cu) column 206. The molding layer 208 may be formed of any molding compounds by any suitable methods, such as Sumitomo G730 by a compression molding process.

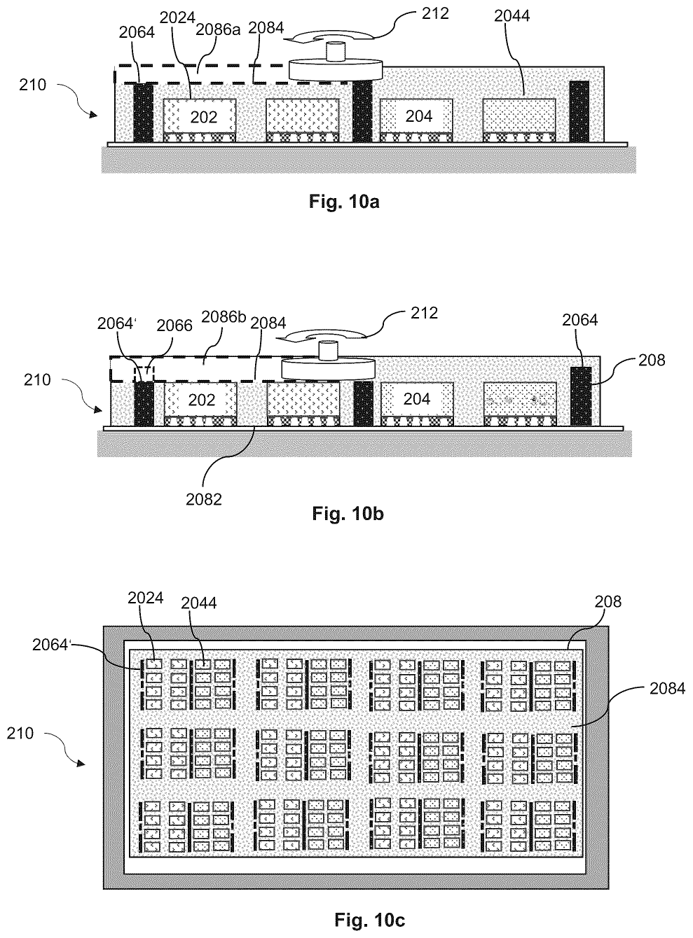

FIGS. 10a to 10c illustrates Step S108 of the panel-level method S100, i.e., thinning the molding layer 208 to a desired thickness for the molded panel 210. As an embodiment, Step S108 is performed in two sub-steps. FIG. 10a shows a cross-sectional view of a first sub-step that a first top portion 2086a (shown as a dash rectangle in FIG. 10a) is removed by a grinding device 212 from the molding layer 208. In the first sub-step, the back surface 2064 of the copper (Cu) column 206 may be retained and exposed from the molding layer 208; while the low-side inactive surface 2024 of the low-side semiconductor die 202 and the high-side inactive surface 2044 of the high-side semiconductor die 204 are still encapsulated. The first sub-step may be performed in a fast manner for enhancing productivity. Then, FIG. 10b shows a cross-sectional view of a second sub-step that a second top portion 2086b (shown as a dash rectangle in FIG. 10b) is further removed from the molding layer 208. Therefore, a second molding surface 2084 is formed for the molding layer 208 after the second sub-step. In particular, the low-side inactive surface 2024 of the low-side semiconductor die 202 and the high-side inactive surface 2044 of the high-side semiconductor die 204 are exposed from the second molding surface 2084 of the molding layer 208. Accordingly, a top portion 2066 (as indicated by a dotted square in FIG. 10a) of the copper (Cu) column 206 is also removed by the grinding device 212 so that a new back surface 2064′ is formed and exposed from the second molding surface 2084 of the molding layer 208. The second sub-step is performed slower than the first sub-step for avoiding any damage to the low-side inactive surface 2024 of the low-side semiconductor die 202 and the high-side inactive surface 2044 of the high-side semiconductor die 204. The second sub-step is also called “lapping” to the molding layer 208. Therefore, the second top portion 2086b is preferred to be smaller than the first top portion 2086a for enhancing productivity. FIG. 10c shows a top view of a portion of the molded panel 210 that the low-side inactive surface 2024 of the low-side semiconductor die 202, the high-side inactive surface 2044 of the high-side semiconductor die 204 and the new back surface 2064′ of the copper (Cu) column 206 are exposed from the second molding surface 2084 of the molding layer 208.

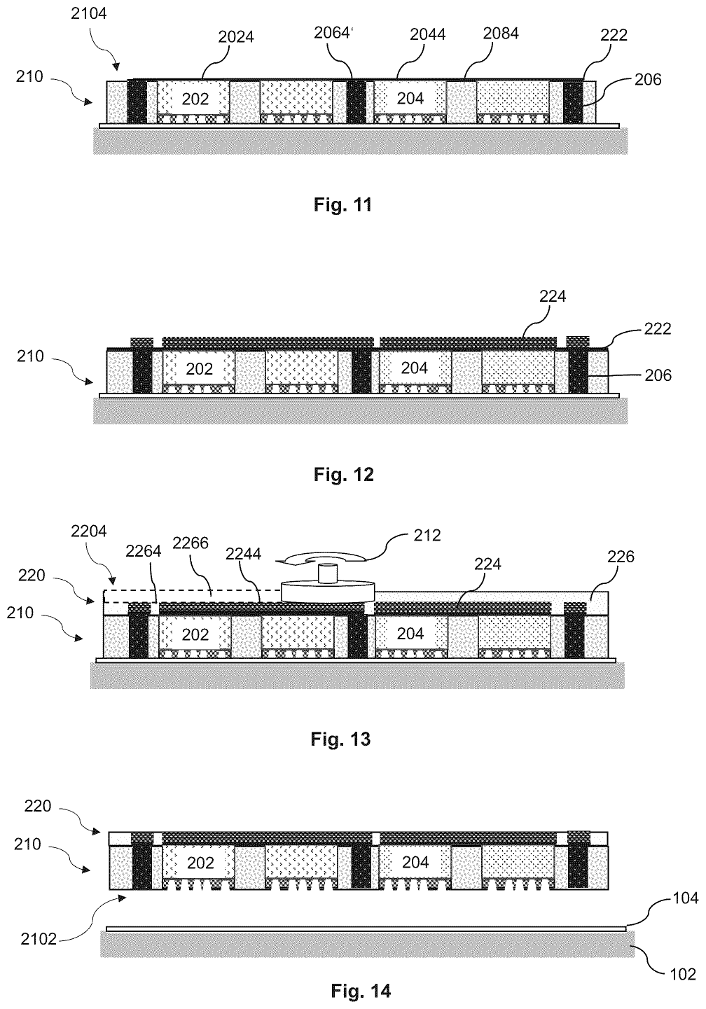

FIGS. 6 to 8 illustrates Step S110 of the panel-level method S100, i.e., forming a back build-up layer 220 on a back surface 2104 of the molded panel 210. The back surface 2104 of the back build-up layer 220 includes the low-side inactive surface 2024 of the low-side semiconductor die 202, the high-side inactive surface 2044 of the high-side semiconductor die 204, the new back surface 2064′ of the copper (Cu) column 206 and the second molding surface 2084 of the molding layer 208. FIG. 11 shows a cross-sectional view that a back seed layer 222 is formed on the back surface 2104 of the molded panel 210. The back seed layer 222 is electrically coupled to the copper (Cu) column 206 at the new back surface 2064′. The back seed layer 222 may be made of any conductive materials by any suitable methods. As an embodiment, the back seed layer 222 is made of titanium/copper (Ti/Cu) composites by sputtering. Then, FIG. 12 shows a cross-sectional view that a back redistribution layer (RDL) 224 is formed on the back seed layer 222. The back RDL 224 may be made of any conductive materials by any suitable methods. As an embodiment, the back RDL 224 is made of copper (Cu) by plating. The back RDL 224 may be also patterned by any suitable methods, such as photolithography. Therefore, the copper (Cu) column 206 is electrically coupled to the back RDL 224 for a current/signal to flow through. Subsequently, FIG. 13 shows a cross-sectional view that a back dielectric layer 226 is formed for encapsulating the back RDL layer 224. The back dielectric layer 226 may be made of any dielectric materials such as molding compounds, silicon dioxide (SiO₂), silicon nitride (Si₃N₄), silicon oxynitride (SiON), aluminum oxide (Al₂O₃), or other materials having similar insulating and structural properties. Then, a top portion 2266 (as shown in a dash rectangle in FIG. 13) of the back dielectric layer 226 is removed by a grinding process of the grinding device 212 for exposing the back RDL layer 224 from the back dielectric layer 226. Therefore, the back build-up layer 220 is formed including the back RDL layer 224 and the back dielectric layer 226. Preferably, the grinding process would also make a top surface 2204 of the back build-up layer 220 to have a substantially flat configuration for the subsequent process in Step 112. The top surface 2204 includes a top surface 2244 of the back RDL 224 and a top surface 2264 of the back dielectric layer 226.

FIGS. 9 & 10 illustrates Step S112 of the panel-level method S100, i.e., transferring the molded panel 210 with the back build-up layer 220 to a second carrier 106a. FIG. 14 shows a cross-sectional view that the molded panel 210 with the back build-up layer 220 is released from the first carrier 102 at an elevated temperature since the first heat and release tape 104 would lose the adhesivity at the elevated temperature. Accordingly, a front surface 2102 of the molded panel 210 is exposed from the first carrier 102 and the first heat and release tape 104. The front surface 2102 of the molded panel 210 includes the low-side active surface 2022 of the low-side semiconductor die 202, the high-side active surface 2042 of the high-side semiconductor die 204, the front surface 2062 of the copper (Cu) column 206 and the first molding surface 2082 of the molding layer 208. Subsequently, FIG. 15 shows a cross-sectional view that the molded panel 210 with the back build-up layer 220 is flipped and then mounted onto the second carrier 106a and a second heat and release tape 108. Due to the substantially flat configuration of the top surface 2204 of the back build-up layer 220 as described above, the molded panel 210 could be mounted on the second carrier 106a and the second heat and release tape 108 rather stably. Meanwhile, the second heat and release tape 108 has sufficient adhesivity at an ambient temperature to secure the molded panel 210 with the back build-up layer 220 in place on a front carrier surface 1062 of the second carrier 106a. It is shown that the low-side pre-vias 2026 of the low-side semiconductor die 202, the high-side pre-vias 2046 of the high-side semiconductor die 204 and the front surface 2062 of the copper (Cu) column 206 are exposed from the first molding surface 2082 of the molding layer 208.

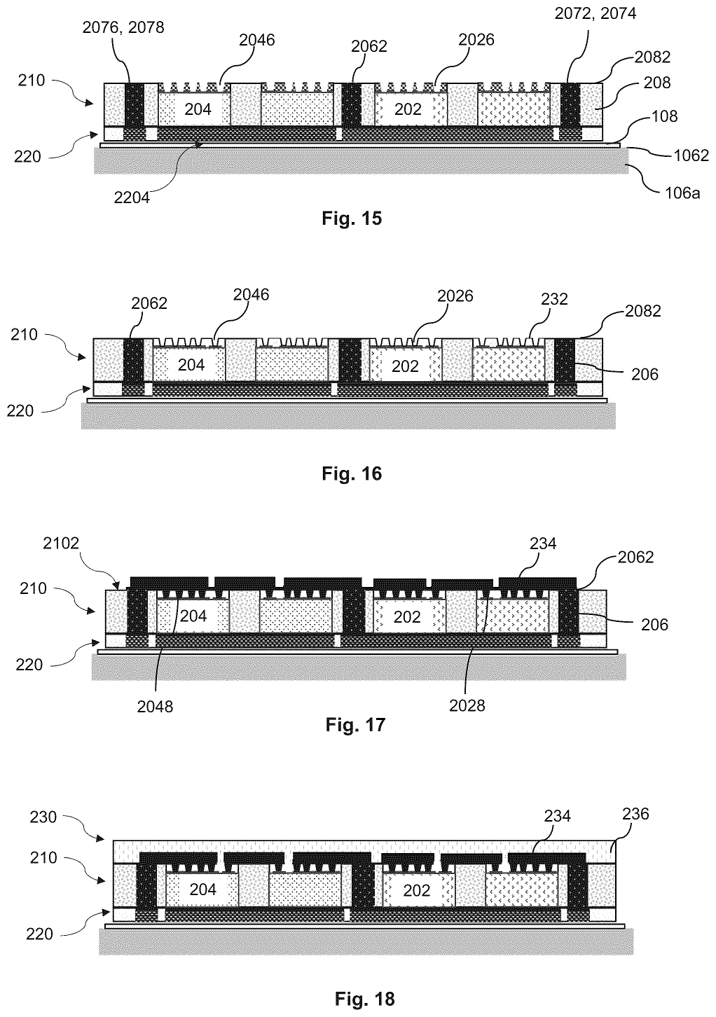

FIGS. 11 to 16 illustrates Step S114 of the panel-level method S100, i.e., forming a front build-up layer 230 on the front surface 2102 of the molded panel 210. FIG. 16 shows a cross-sectional view that a first front seed layer 232 is formed conformally on the front surface 2102 of the molded panel 210 by following contours of the low-side pre-vias 2026 of the low-side semiconductor die 202, the high-side pre-vias 2046 of the high-side semiconductor die 204, the front surface 2062 of the copper (Cu) column 206 and the first molding surface 2082 of the molding layer 208. The first front seed layer 232 may be made of any conductive materials by any suitable methods. As an embodiment, the first front seed layer 232 is made of titanium/copper (Ti/Cu) composites by sputtering. As a result, the first front seed layer 232 is electrically coupled to the copper (Cu) column 206 at the front surface 2062. After formation of the first front seed layer 232, a procedure of Die Location Check (DLC) may be performed for checking whether the low-side semiconductor die 202 and the high-side semiconductor die 204 are bonded to their pre-determined positions. If not, the procedure of DLC would collect true locations of the low-side semiconductor die 202 and the high-side semiconductor die 204 in the molded panel 210.

FIG. 17 shows a cross-sectional view that the low-side pre-vias 2026 of the low-side semiconductor die 202 and the high-side pre-vias 2046 of the high-side semiconductor die 204 are filled with conductive materials and turned into the low-side filled vias 2028 of the low-side semiconductor die 202 and the high-side filled vias 2048 of the high-side semiconductor die 204 respectively, according to the true locations of the low-side semiconductor die 202 and the high-side semiconductor die 204. Then, a first front redistribution layer (RDL) 234 is formed on the front surface 2102 of the molded panel 210. The first front RDL 234 may be made of any conducting materials such as metals by any suitable method. Preferably, the first front RDL 234 is made of copper (Cu) by plating. Accordingly, the first front RDL 234 is electrically coupled to the low-side filled vias 2028 of the low-side semiconductor die 202, the high-side filled vias 2048 of the high-side semiconductor die 204 and the front surface 2062 of the copper (Cu) column 206. Therefore, the functional circuitries of the low-side semiconductor die 202 and the high-side semiconductor die 204 are led out from the contact pads at the low-side active surface 2022 of the low-side semiconductor die 202 and the high-side active surface 2042 of the high-side semiconductor die 204 respectively to the back RDL layer 224 of the back build-up layer 220 through the first front RDL 234 and the copper (Cu) column 206. Alternatively, the low-side pre-vias 2026 of the low-side semiconductor die 202 and the high-side pre-vias 2046 of the high-side semiconductor die 204 may be filled before bonding the low-side semiconductor die 202 and the high-side semiconductor die 204 onto the first carrier 102 and the first heat and release tape 104 as shown in FIGS. 8a to 8f. Accordingly, the fillings of the low-side pre-vias 2026 of the low-side semiconductor die 202 and the high-side pre-vias 2046 of the high-side semiconductor die 204 are skipped here.

FIG. 18 shows a cross-sectional view that a first front dielectric layer 236 is formed for encapsulating the first front RDL 234. The first front dielectric layer 236 may be made of any dielectric materials such as molding compounds, silicon dioxide (SiO₂), silicon nitride (Si₃N₄), silicon oxynitride (SiON), aluminum oxide (Al₂O₃), or other materials having similar insulating and structural properties. The first front dielectric layer 236 may be formed by any suitable methods, such as compression molding of Sumitomo G730. Preferably, the first front dielectric layer 236 is formed by film lamination for controlling the first front dielectric layer 236 to a certain first thickness, such as 100 micrometers (μm). Before forming the first front dielectric layer 236, the first front seed layer 232 is removed by any suitable methods such as chemical etching to make sure that the first front RDL 234 are electrically insulated among each other. As a result, the front build-up layer 230 is formed including the first front RDL 234 and the first front dielectric layer 236.

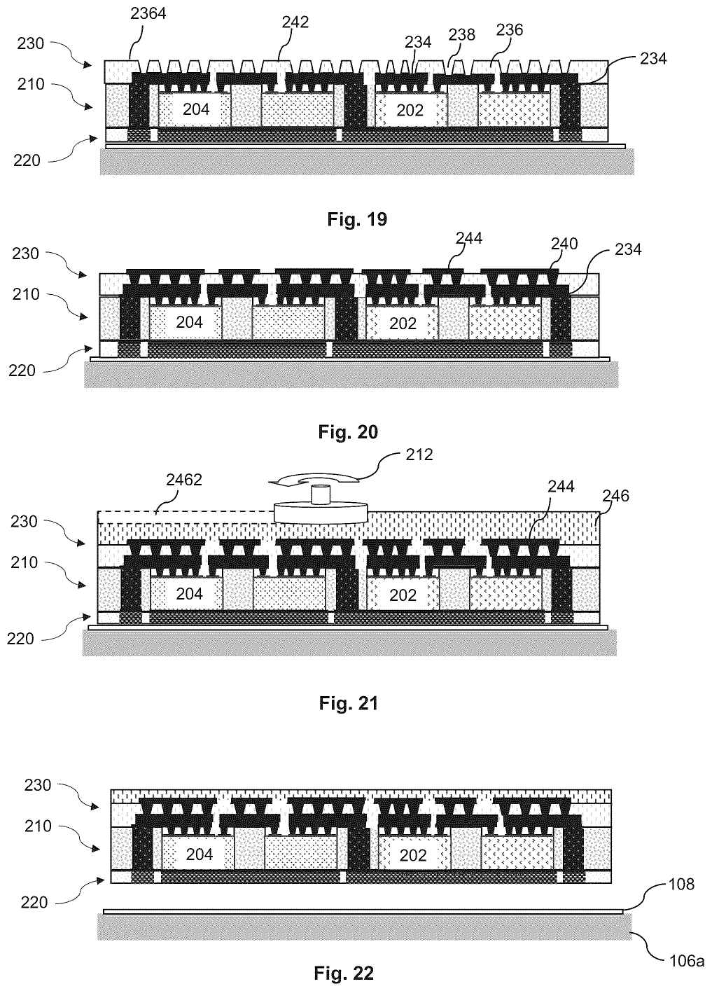

FIG. 19 shows a cross-sectional view that multiple grooves 238 are formed in the first front dielectric layer 236. The grooves 238 may be formed by any suitable methods at the panel-level, such as laser drilling, photolithography or photoimageable technologies according to the design of the semiconductor package 20. For photolithography or photoimageable technologies, the first front dielectric layer 236 may be made of solder mask materials or photoimageable dielectric materials to make the groves 238 in the first front dielectric layer 236. The solder mask materials may include resin (such as epoxy, polyurethane, acrylic), hardners, fillers, dyes, as well as UV-reactive substances. Preferably, the solder mask materials include TAIYO PSR-4000 series. Accordingly, a portion of the first front RDL 234 is exposed from the first front dielectric layer 236 through the grooves 238. Then, a second front seed layer 242 is formed conformally by following contours of the grooves 238 and a top surface 2364 of the first front dielectric layer 236. The second front seed layer 242 may be made of any conductive materials by any suitable methods. As an embodiment, the second front seed layer 242 is made of titanium/copper (Ti/Cu) composites by sputtering. Thus, the second front seed layer 242 is electrically coupled to the first front RDL 234. FIG. 20 shows a cross-sectional view that the grooves 238 are filled with conductive materials such as copper (Cu) or titanium/copper (Ti/Cu) composites by plating; and turned into filled grooves 240 accordingly. Then, a second front redistribution layer (RDL) 244 is formed on the filled grooves 240 and the second front seed layer 242. The second front RDL 244 may be made of any conducting materials such as metals by any suitable method. Preferably, the second front RDL 244 is made of copper (Cu) by plating. Accordingly, the second front RDL 244 is electrically coupled to the first front RDL 234 through the filled grooves 240.

FIG. 21 shows a cross-sectional view that a second front dielectric layer 246 is formed for encapsulating the second front RDL 244. The second front dielectric layer 246 may be made of any dielectric materials such as molding compounds, silicon dioxide (SiO₂), silicon nitride (Si₃N₄), silicon oxynitride (SiON), aluminum oxide (Al₂O₃), or other materials having similar insulating and structural properties. The second front dielectric layer 246 may be formed by any suitable methods, such as compression molding or film lamination. Subsequently, a grinding process may be performed by the grinding device 212 to the second front dielectric layer 246 to remove a top portion 2462 of the second front dielectric layer 246 for reducing the second front dielectric layer 246 to a certain second thickness according to the design of the semiconductor package 20. Therefore, it is shown here that the front build-up layer 230 has a first layer including the first front RDL 234 and the first front dielectric layer 236; a second layer including the second front RDL 244 and the second front dielectric layer 246, and the filled grooves 240 for electrically coupling the first layer and the second layer. It is understood that the front build-up layer 230 may include more layers the same as or similar to the first layer or the second layer, as well as more filled grooves the same as or similar to the filled grooves 240 for electrically coupling the more layers of the front build-up layer 230. Before forming the second front dielectric layer 246, the second front seed layer 242 is removed by any suitable methods such as chemical etching to make sure that the second front RDL 244 are electrically insulated among each other.

FIG. 22 illustrates Step S116 of the panel-level method S100, i.e., releasing the molded panel 210 with the back build-up layer 220 and the front build-up layer 230 (for example, including the first layer and the second layer as described above) from the second carrier 106a and the second heat and release tape 108 at an elevated temperature since the second heat and release tape 108 would lose the adhesivity at the elevated temperature. Accordingly, the back build-up layer 220 is exposed from the second carrier 106a and the second heat and release tape 108.

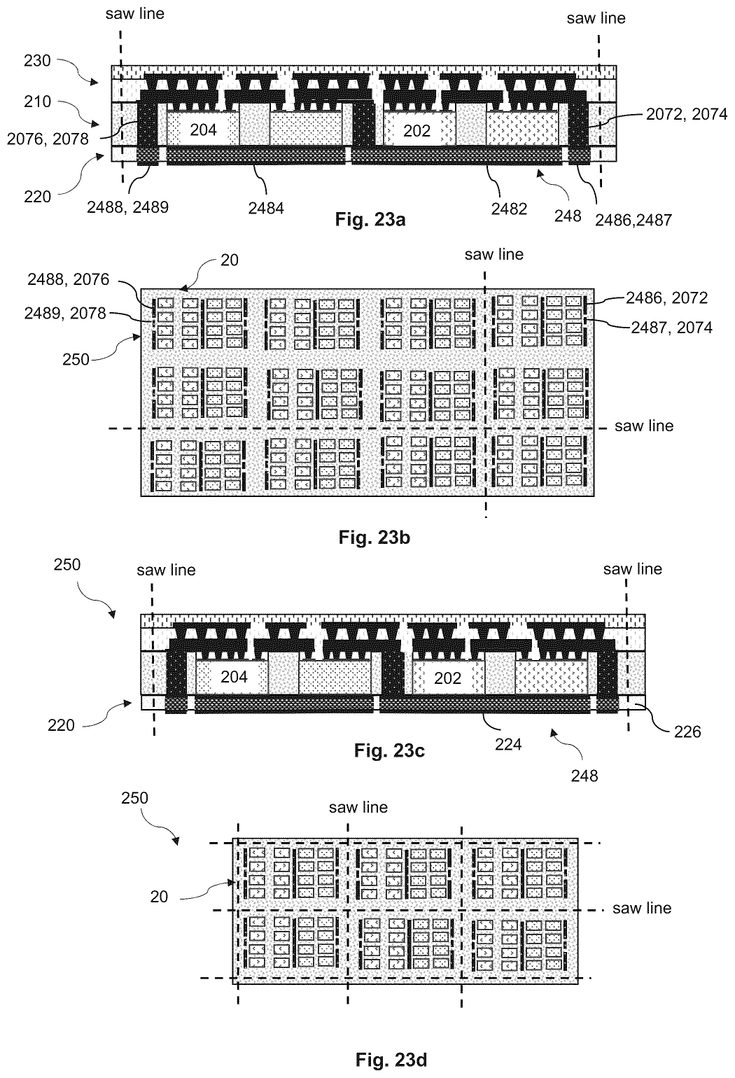

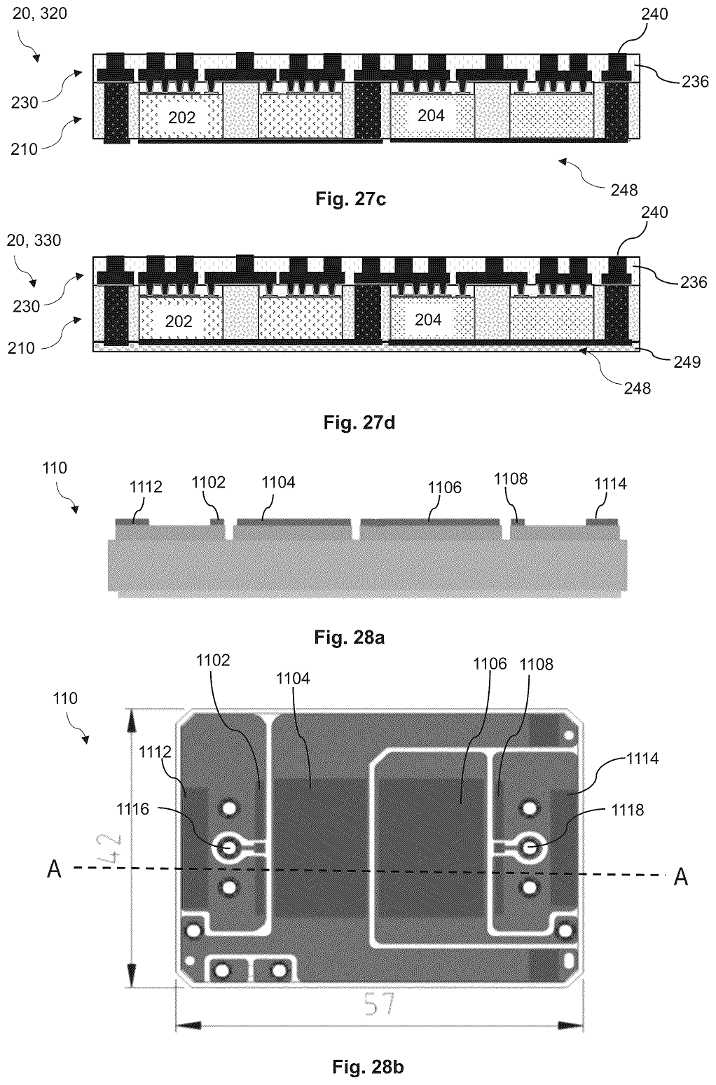

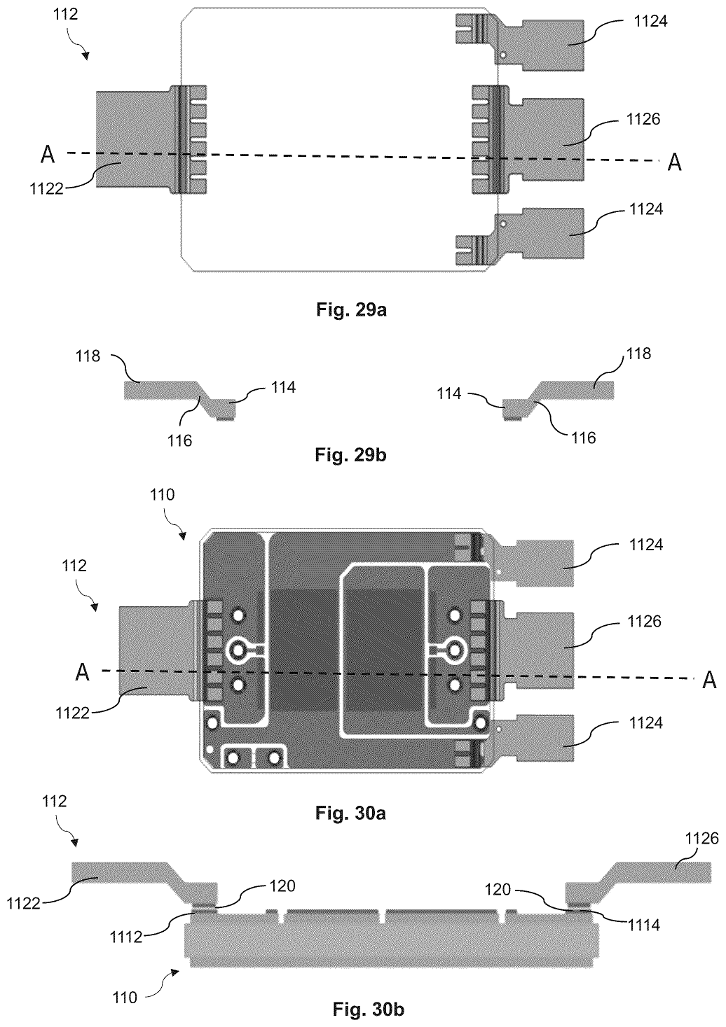

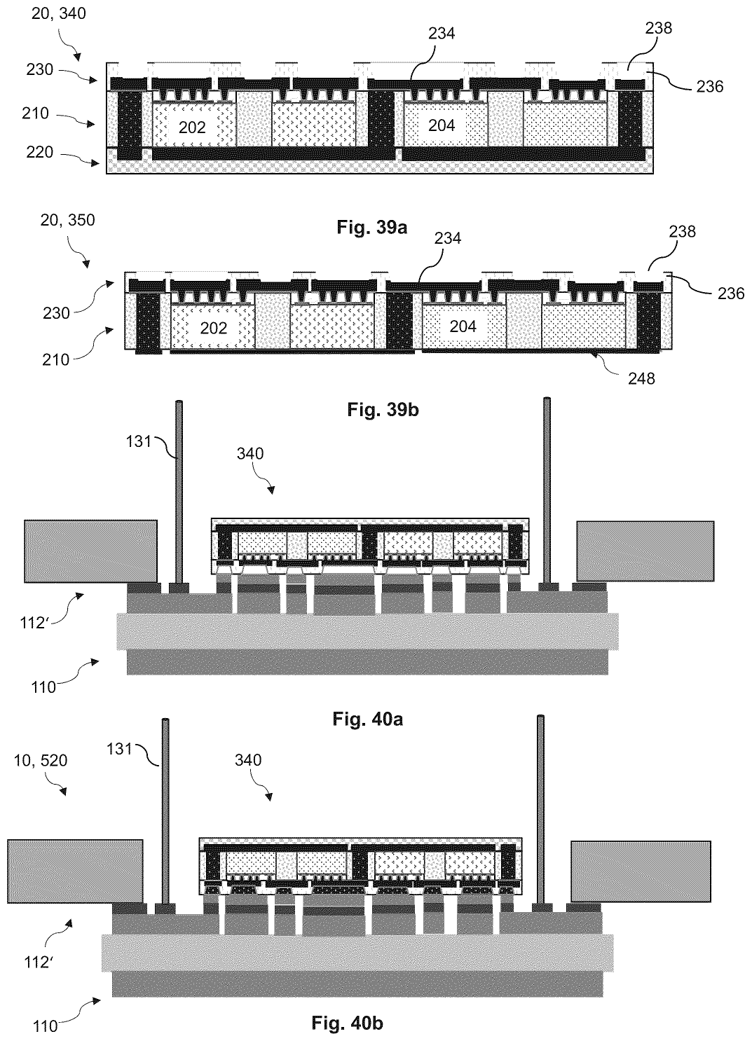

FIGS. 23a to 23d illustrate a first embodiment of Steps S118 & S120 of the panel-level method S100. It is noted that Step S118 is an optional step and may be skipped such as the semiconductor packages 200 as shown in FIGS. 27a to 27d and FIG. 39b where the external connection layer 248 is directly formed on the back surface 2104 of the molded panel 210. FIG. 23a shows a cross-sectional view that the molded panel 210 with the back build-up layer 220 and the front build-up layer 230 (including the first layer and the second layer as described above) is singulated along the saw lines into multiple sub-panels 250 which have a smaller size than the molded panel 210 as a whole. As an embodiment, the sub-panel 250 has a size of 212 millimeters (mm)×216 millimeters (mm). FIG. 23b shows a top view of that the sub-panel 250 has 6semiconductor packages 200 arranged in a matrix of 2 rows and 3 columns. It is understood that the sub-panel 250 may have other numbers of the semiconductor package 20. Then, FIG. 23c shows a cross-sectional view that the external connection layer 248 is formed on the back RDL layer 224 exposed from the back dielectric layer 226 of the back build-up layer 220 at the sub-panel 250. The external connection layer 248 may be formed by any conductive materials such as metals by any suitable methods to make it as a surface finish for providing a very flat surface for Input/Output (I/O). For example, the surface finish may be made of a single layer of metals such as Tin or a single layer of metal composites such as nickel/gold. Alternatively, the surface finish may be made of multiple layers. In some embodiments, the surface finish is made of electroless nickel immersion gold (enig) which has a two-layer metallic surface finish with a first layer of nickel using an electroless chemical reaction; and then a very thin layer of gold plated onto the layer of nickel. In other embodiments, the surface finish is made of electroless eickel electroless palladium immersion gold (enepig) which is formed by deposition of electroless nickel, followed by electroless palladium, and finally an immersion gold flash. Preferably, the external connection layer 248 is formed of silver (Ag) by plating to make the surface finish. The surface finish is chemically compatible with the I/O for improving stability of connection. The surface finish may have a thickness in a range of 1 to 10 micrometers (μm), preferably 1 to 5 micrometers (μm), or more preferably 1 to 3 micrometers (μ). Finally, FIG. 23d shows a cross-sectional view that the sub-panel 250 with the external connection layer 248 is further singulated along the saw lines into the individual semiconductor packages 200 according to the design of the semiconductor package 20.

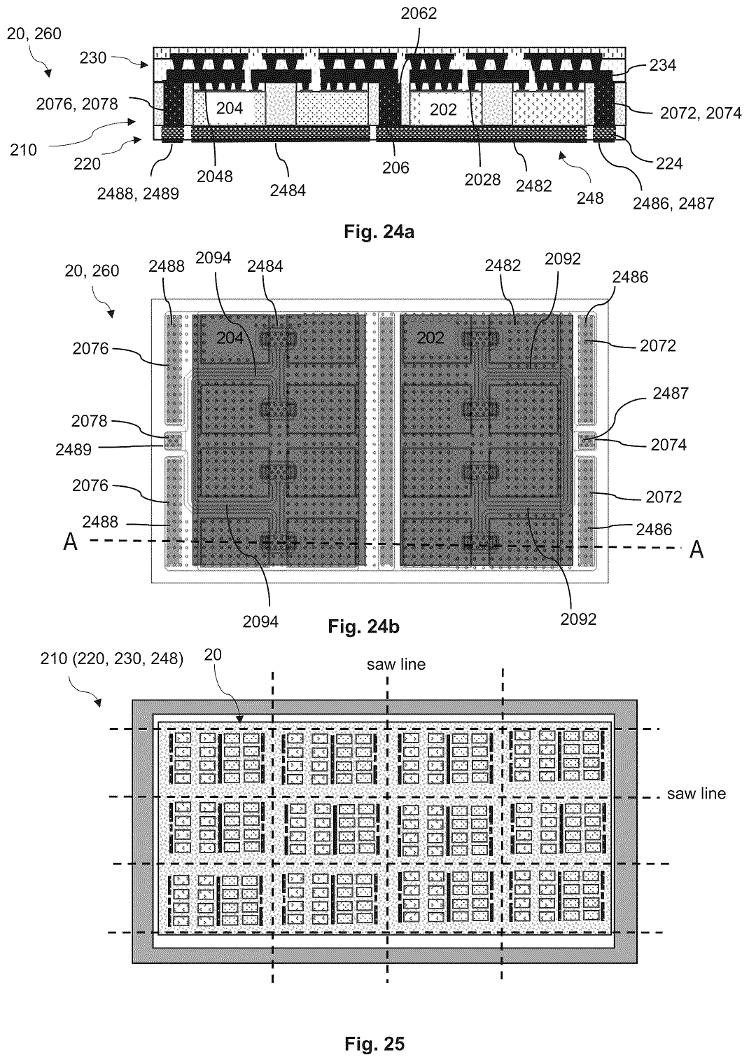

FIGS. 24a & 24b illustrate an embodiment 260 of the semiconductor package 20 obtained from the panel-level method S100. FIG. 24a shows a cross-sectional view of the embodiment 260 that all the interconnections within the semiconductor package 20 are formed by direct copper (Cu), i.e., the interconnections between the contact pads and the low-side filled vias 2028 and the high-side filled vias 2048 of the low-side semiconductor die 202 and the high-side semiconductor die 204 respectively, between the low-side filled vias 2028 and the high-side filled vias 2048 and the first front RDL 234 of the front build-up layer 230 respectively, between the first front RDL 234 of the front build-up layer 230 and the copper (Cu) column 206, and between the copper (Cu) column 206 and the back RDL layer 224 of the back build-up layer 220. The direct copper (Cu) also includes the interconnections between the first front RDL 234 and the second front RDL 244 through the filled grooves 240 in the front build-up layer 230. In this way, the functional circuitries of the low-side semiconductor die 202 and the high-side semiconductor die 204 are led out from the contact pads at the low-side active surface 2022 and the high-side active surface 2042 to the back RDL layer 224 of the back build-up layer 220 at the low-side inactive surface 2024 of the low-side semiconductor die 202 and the high-side inactive surface 2044 of the high-side semiconductor die 204 respectively through the embodiment 260; and further led out to external devices such as a substrate 110 as shown in FIGS. 28a & 28b (either a direct bonded copper (DBC) substrate or a ceramic substrate) or a PCB (not shown) through the back RDL layer 224 of the back build-up layer 220 and the external connection layer 248. The interconnections of the direct copper (Cu) have the advantage of rapid switching, high frequencies, as well as high voltages and large currents. Therefore, the semiconductor package 20 is suitable for high power efficiency. In addition, the interconnections of the direct copper (Cu) also enhance heat dissipation of the semiconductor package 20 and thus make the power module 10 more reliable for operation, particularly under a high temperature.

FIG. 24b shows a top view of the embodiment 260 in which the semiconductor package 20 has a package size of 37 millimeters (mm)×23 millimeters (mm) with 8 low-side semiconductor dies 202 arranged in a matrix of 2 columns and 4 rows on a right side (low-side); and 8 high-side semiconductor dies arranged in another matrix of 2 columns and 4 rows at the left side (high-side). The cross-sectional view in FIG. 24a is demonstrated along the cross-sectional A-A line in FIG. 24b. It is understood that the semiconductor package 20 may have other arrangements for the 8 low-side semiconductor dies 202 and the 8 high-side semiconductor dies 204. It is also understood that the semiconductor package 20 may have other numbers of the low-side semiconductor dies 202 and the high-side semiconductor dies 204. A layout of the semiconductor package 20 is also shown here for the metal-oxide-semiconductor field-effect transistor (MOSFET) that the two first copper columns 2072 and the one second copper column 2074 of the copper (Cu) column 206 functioning as two low-side sources and one low-side gate for the 8 low-side semiconductor dies 202; and the two third copper columns 2076 and the one fourth copper column 2078 of the copper (Cu) column 206 functioning as two high-side sources and one high-side gate for the 8 high-side semiconductor dies 204. The external connection layer 248 also has one low-side external connection layer 2482 covering the low-side inactive surfaces 2024 of the 8 low-side semiconductor dies 202 and one high-side external connection layer 2484 covering the high-side inactive surfaces 2044 of the 8 high-side semiconductor dies 204 functioning as a low-side drain and a high-side drain respectively. The external connection layer 248 further has a first external connection layer 2486 and a second external connection layer 2487 electrically coupled to the two first copper columns 2072 and the one second copper column 2074 of the copper (Cu) column 206 respectively. The external connection layer 248 also has a third external connection layer 2488 and a fourth external connection layer 2489 electrically coupled to the two third copper columns 2076 and the one fourth copper column 2078 of the copper (Cu) column 206 respectively. In addition, FIG. 24b also shows that the semiconductor package 20 has a low-side gate current path 2092 of a same length between all the 8 low-side semiconductor dies 202 and the one second copper column 2074 as the low-side gate; and a high-side gate current path 2094 of another length between all 8 the high-side semiconductor die 204 and the one fourth copper column 2078 as the high-side gate. Therefore, the semiconductor package 20 could be also controlled exactly at the same time, i.e., turned to the “ON” statues or the “OFF” status simultaneously. The lengths of the low-side gate current path 2092 and the high-side gate current path 2094 may be same or different. It is understood that the semiconductor package 20 may have other layouts for the low-side source(s), the low-side gate and the low-side drain, and for the high-side source(s), the high-side gate and the high-side drain. These variations to the layout of the semiconductor package 20 are also within the scope of the present disclosure.

FIG. 25 illustrates a second embodiment of Step S118 & S120 of the panel-level method S100. Compared with the first embodiment described above, the molded panel 210 would not singulated into the sub-panels 250. Instead, the external connection layer 248 is formed on the back RDL layer 224 exposed from the back dielectric layer 226 of the back build-up layer 220 at the molded panel 210. Then, the molded panel 210 (with the back build-up layer 220, the front build-up layer 230 and the external connection layer 248) is directly singulated along the saw lines into the individual semiconductor packages 200 according to the design of the semiconductor package 20.

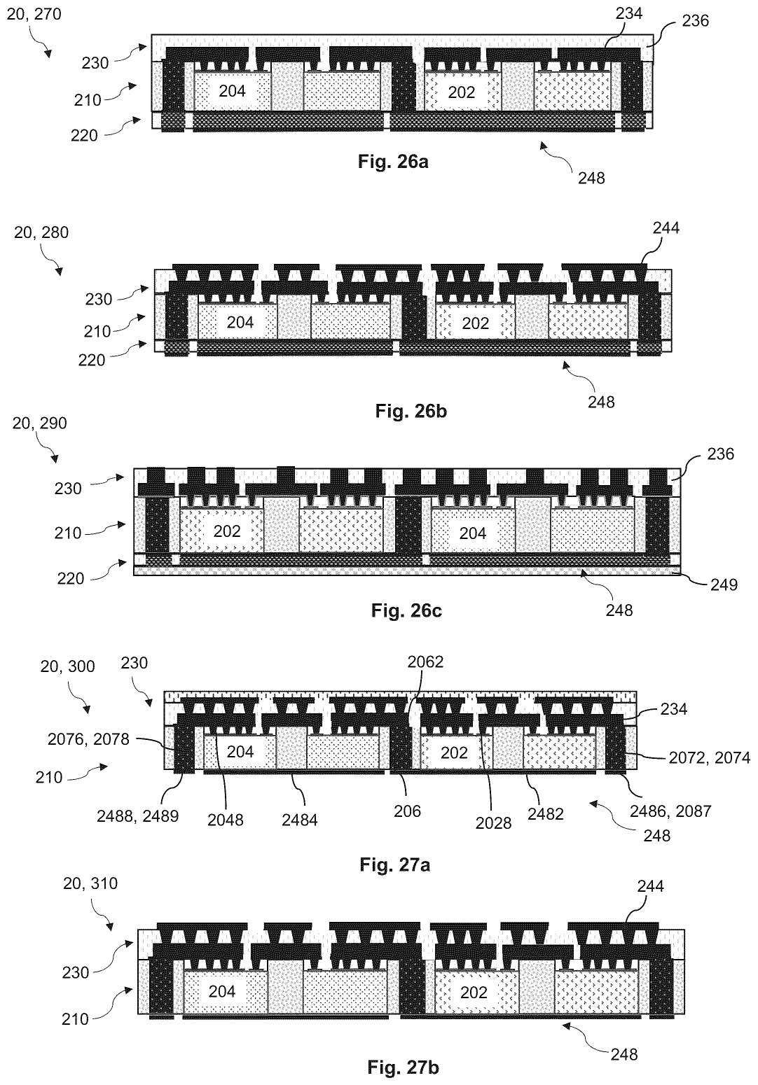

FIGS. 26a to 26c illustrate other embodiments 270, 280, 290 of the semiconductor package 20 obtained from the panel-level method S100. Similar to the embodiment 260, all the embodiments 270, 280 and 290 have the back build-up layer 220 and the front build-up layer 230. FIG. 26a shows a cross-sectional view of the embodiment 270. Compared with the embodiment 260, the front build-up layer 230 of the embodiment 270 has only the first layer without the second layer as described above. Meanwhile, it is understood that other embodiments with the front build-up layer 230 may have 3, 4 or more layers are also within the scope of the present disclosure. FIG. 26b shows a cross-sectional view of the embodiment 280. Compared with the embodiment 260, the front build-up layer 230 of the embodiment 280 does not have the second front dielectric layer 246; and accordingly, the second front RDL 244 is not encapsulated. FIG. 26c shows a cross-sectional view of the embodiment 290. Compared with the embodiment 260, the embodiment 290 has an external connection dielectric layer 249 encapsulating the external connection layer 248; while the front build-up layer 230 thereof does not have the second layer and the filled grooves 240 are exposed from the first front dielectric layer 236 accordingly.

FIGS. 27a to 27d illustrate other embodiments 300, 310, 320 and 330 of the semiconductor package 20 obtained from the panel-level method S100. Compared with the embodiment 260, all the embodiments 300, 310, 320 and 330 do not have the back build-up layer 220; and accordingly, the external connection layer 248 is formed directly on the back surface 2104 of the molded panel 210. FIG. 27a shows a cross-sectional view of the embodiment 300. Compared with the embodiment 260, in the embodiment 300 the low-side external connection layer 2482 is formed in contact with the low-side inactive surface 2024 of the low-side semiconductor die 202, the high-side external connection layer 2484 is formed in contact with and the high-side inactive surface 2044 of the high-side semiconductor die 204, the first external connection layer 2486 is formed in contact with the first copper columns 2072, the second external connection layer 2487 is formed in contact with the second copper column 2074, a third external connection layer 2488 is formed in contact with the third copper column 2076, and a fourth external connection layer 2489 is formed in contact with the fourth copper columns 2078. Alternatively, if the incoming low-side semiconductor wafer and the incoming high-side semiconductor wafer have the conductive layers on their inactive wafer surfaces respectively. Then, this process of forming the external connection layer 248 can be skipped since the conductive layers of the incoming low-side semiconductor wafer and the incoming high-side semiconductor wafer would be retained and function as the external connection layer 248 described above. FIG. 27b show a cross-sectional view of the embodiment 310. Compared with the embodiment 300, the front build-up layer 230 of the embodiment 310 does not have the second front dielectric layer 246; and the back RDL 244 is exposed. FIG. 27c shows a cross-sectional view of the embodiment 320. Compared with the embodiment 310, the front build-up layer 230 of the embodiment 320 does not have the second layer; and the filled grooves 240 are exposed from the first front dielectric layer 236. FIG. 27d shows a cross-sectional view of the embodiment 330. Compared with the embodiment 320, the embodiment 330 further has the external connection dielectric layer 249 encapsulating the external connection layer 248; while the filled grooves 240 are exposed from the first front dielectric layer 236.

FIGS. 28a to 30b illustrate Step S122 of the panel-level method S100, i.e., preparing the substrate 110 (either the direct bonded copper (DBC) substrate or the ceramic substrate) with an external connecting mechanism 112. The substrate 110 may be made of any insulating materials including various ceramic materials, aluminum oxide (Al₂O₃), silicon nitride (Si₃N₄), aluminum nitride (AIN), HPS (alumina doped with around 9% ZrO₂ or zirconia toughened alumina (ZTA)). FIG. 28a shows a cross-sectional view of the substrate 110 which has (in sequence from the left to the right) an Alternating Current (AC) conductive layer 1112, a first conductive layer 1102, a second conductive layer 1104, a third conductive layer 1106, a fourth conductive layer 1108, and a Direct Current (DC) conductive layer 1114 separated from each other. The conductive layers 1112, 1102, 1104, 1106, 1108, 1114 may be made of any conducting materials, such as metals by any suitable methods to make them as a surface finish for providing a very flat surface for Input/Output (I/O). For example, the surface finish may be made of a single layer of metals such as Tin or a single layer of metal composites such as nickel/gold. Alternatively, the surface finish may be made of multiple layers. In some embodiments, the surface finish is made of electroless nickel immersion gold (enig) which has a two-layer metallic surface finish with a first layer of nickel using an electroless chemical reaction; and then a very thin layer of gold plated onto the layer of nickel. In other embodiments, the surface finish is made of electroless nickel electroless palladium immersion gold (enepig) which is formed by deposition of electroless nickel, followed by electroless palladium, and finally an immersion gold flash. Preferably, the conductive layers 1112, 1102, 1104, 1106, 1108, 1114 are made of silver (Ag) by plating to make them as the surface finish. The surface finish is chemically compatible with the I/O for improving stability of connection. The surface finish may have a thickness in a range of 1 to 10 micrometers (μm), preferably 1 to 5 micrometers (um), or more preferably 1 to 3 micrometers (μm). FIG. 28b shows a top view of the substrate 110 as described in FIG. 28a. As an embodiment, for the semiconductor package 20 having the package size of 37 millimeters (mm)×23 millimeters (mm), the substrate 110 may have a substrate size of 57 millimeters (mm)×42 millimeters (mm) accordingly. The substrate 110 may have a substrate thickness for making the substrate 110 sufficiently rigid to carry the semiconductor package 20. As an embodiment, the substrate thickness of the substrate 110 may be around 3 millimeters (mm). It is understood that the substrate size and the substrate thickness may be varied according to designs of the power module 10; and all the variations would be within the scope of the present disclosure. FIG. 28b further shows that the substrate 110 has low-side routings 1116 and high-side routings 1118 electrically coupled to the first conductive layer 1102 and the fourth conductive layer 1108 respectively.

As an embodiment, FIG. 29a shows a top view of the external connecting mechanism 112 which includes one Alternating Current (AC) copper (Cu) clip 1122 on a left side (high-side), and two Direct Current Positive (DC+) copper (Cu) clips 1124 and one Direct Current Negative (DC−) copper (Cu) clip 1126 on a right side (low-side). FIG. 29b shows a cross-sectional view of the external connecting mechanism 112 at a cross-sectional line A-A in FIG. 29a. It is shown that the copper (Cu) clips 1122, 1124, 1126 have a same or similar structure with a first part 114 having a substantially flat configuration, a third part 118 having another substantially flat configuration and a second part 116 having a Z-shape configuration. The second part 116 couples the first part 114 and the third part 118 robustly for making the external connecting mechanism 112 into a monolithic structure.

FIGS. 30a & 30b show a top view and a cross-sectional view that the external connecting mechanism 112 are coupled to the substrate 110 by coupling the AC copper (Cu) clip 1122 to the AC conductive layer 1112, and the DC+ copper (Cu) clips 1124 and the DC-copper (Cu) clip 1126 to the DC conductive layer 1114. In particular, the coupling must generate a first electrically conducting joint 120 between the substrate 110 and the external connecting mechanism 112. The coupling may be performed by any suitable methods, such as electrically conducting adhesives including epoxy-silver pastes. Preferably, the coupling is performed by silver sintering which utilizes silver (Ag) particles and high-temperature sintering for making the first electrically conducting joint 120 electrically conducting and also strong and reliable between the substrate 110 and the external connecting mechanism 112.

Accordingly, the power module 10 may function as an inverter for converting DC to AC. The DC+copper (Cu) clips 1124 and the DC− copper (Cu) clip 1126 work as input terminals electrically connected to positive electrodes and a negative electrode of a Direct Current (DC) power source (such as a battery or other electricity storing devices) respectively; while the AC copper (Cu) clip 1122 works as an output terminal electrically connected to an Alternating Current (AC) electric appliance (such as an electric motor). The function of the inverters is realized by the semiconductor package 20 in which the input terminals are configured to electrically couple the DC power source to the low-side semiconductor die 202; and the output terminal is configured to electrically couple the high-side semiconductor die 204 to the AC electric appliance. Therefore, the low voltage of DC from the DC power source is converted to the high voltage of AC to the AC electric appliance by the power module 10.

Alternatively, the power module 10 may function as a rectifier for converting AC to DC. The AC copper (Cu) clip 1122 works as an input terminal configured to be electrically connected to an Alternating Current (AC) power source (such as a domestic electrical grid); while the DC+ copper (Cu) clips 1124 and the DC− copper (Cu) clip 1126 work as output terminals configured to be electrically connected to positive electrodes and a negative electrode of a Direct Current (DC) power storing device or battery respectively. Therefore, the high voltage of AC from the AC power source is converted to the low voltage of DC to the DC electricity storing devices by the power module 10. It is understood that what FIG. 30 shows here is only an embodiment of the power module 10, and other designs of the power module 10 are also included within the scope of the present disclosure.

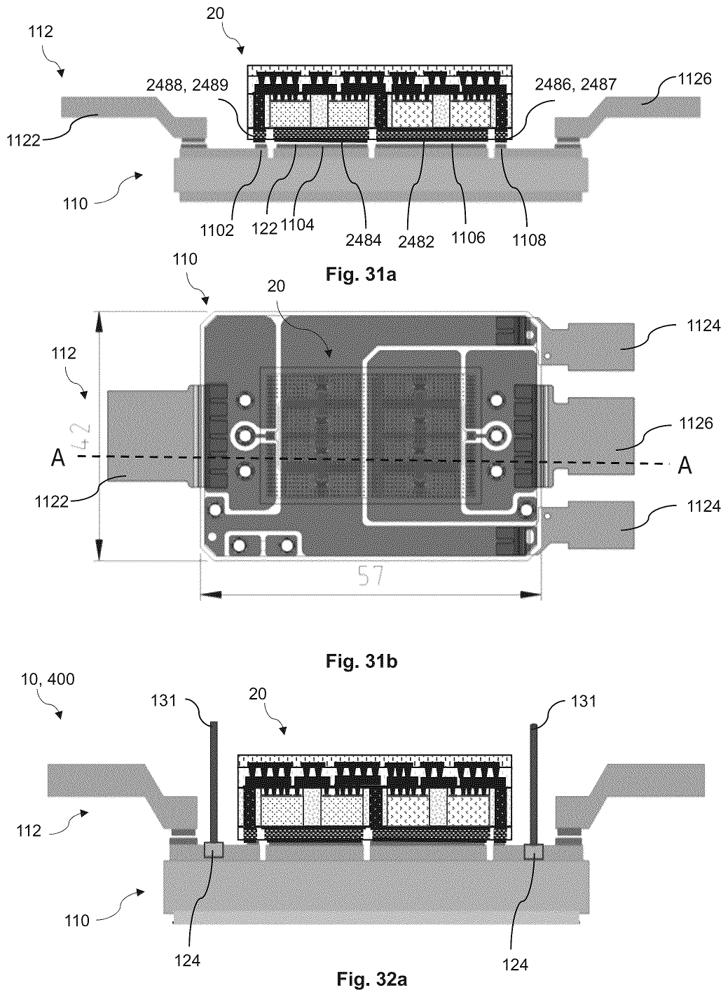

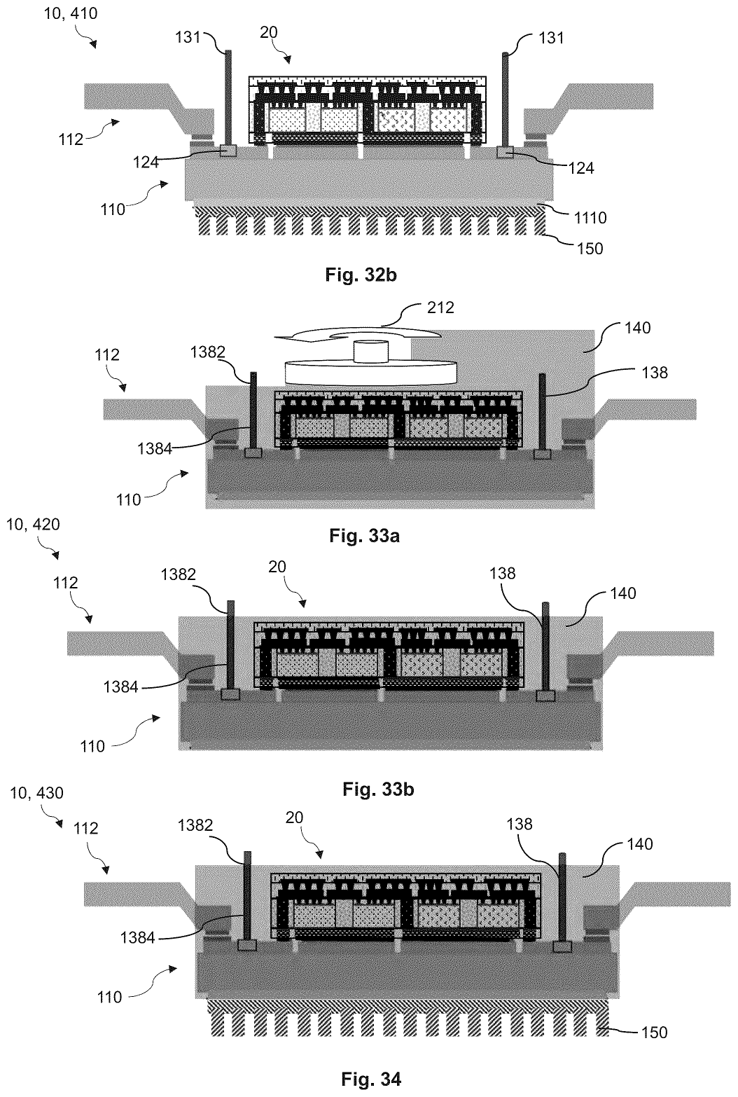

FIGS. 31a to 32a illustrate a first embodiment of Step S124 of the panel-level method S100 and an embodiment 400 of the power module 10. FIGS. 31a& 31b show a cross-sectional view and a top view that the semiconductor package 20 is mounted and coupled onto the substrate 110 by coupling the first and second external connection layers 2486, 2487 to the fourth conductive layer 1108, the one low-side external connection layer 2482 to the third conductive layer 1106, the one high-side external connection layer 2484 to the second conductive layer 1104, and the third and fourth external connection layer 2488, 2489 to the fourth conductive layer 1108. Similarly, the coupling must generate a second electrically conducting joint 122 between the substrate 110 and the semiconductor package 20. The coupling may be performed by any suitable methods, such as electrically conducting adhesives including epoxy-silver pastes. Preferably, the coupling is performed by silver sintering as described above. Since all the one low-side external connection layer 2482, the one high-side external connection layer 2484, the first and the second external connection layers 2486, 2487, the third and fourth external connection layers 2488, 2489, the first conductive layer 1102, the second conductive layer 1104, the third conductive layer 1106, the fourth conductive layer 1108 and the second electrically conducting joint 122 are made of conductive materials, the functional circuitries of the low-side semiconductor die 202 and the high-side semiconductor die 204 would be led out from the one low-side external connection layer 2482 and the one high-side external connection layer 2484 of the semiconductor package 20 to the second conductive layer 1104 and the third conductive layer 1106 of the substrate 110 through the second electrically conducting joint 122. The embodiment 260 is shown here as the semiconductor package 20, but it is understood that other embodiments described above can also be mounted and coupled as the semiconductor package 20 onto the substrate 110. In addition, since the second conductive layer 1104 and the third conductive layer 1106 of the substrate 110, and the one low-side external connection layer 2482 and the one high-side external connection layer 2484 of the external connection layer 248 are made as the surface finish as described above, they all have very flat surfaces which would make the second electrically conducting joint 122 more robust and reliable, particularly when they are made of same conducting materials, preferably plated silver (Ag).

FIG. 32a shows a cross-sectional view that monolithic signal leads 138 are mounted and coupled onto the direct bonded copper (DBC) substrate 110. The coupling must generate a third electrically conducting joint 124 between the substrate 110 and the monolithic signal leads 138. In particular, the monolithic signal leads 138 have a lead height greater than a package thickness of the semiconductor package 20. The monolithic signal leads 138 may be made of any conducting materials such as metals. Preferably, the monolithic signal leads 138 are made of copper (Cu) as Cu pins accordingly. The monolithic signal leads 138 are electrically coupled to a gate driver (not shown) which control performance of the power module 10, such as switches between an “ON” status and an “OFF” status for the power inverters. It is understood that the monolithic signal leads 138 may be mounted before mounting the semiconductor package 20 onto the substrate 110. Accordingly, the embodiment 400 of the power module 10 is formed as shown in FIG. 32a which may be suitable for various power modules 100 such as half-bridge inverters.

FIG. 32b illustrate an optional Step S126 of the panel-level method S100, i.e., attaching a heat dissipation device to the substrate 110 to the embodiment 400 for forming another embodiment 410 of the power module 10. FIG. 32b shows a cross-sectional view that a heat sink 150 as an embodiment of the heat dissipation device is attached to a bottom surface 1110 of the substrate 110 for dissipating heat generated by the semiconductor package 20 more efficiently.

FIGS. 33a & 33b illustrate an optional Step S128 of the panel-level method S100 and an embodiment 420 of the power module 10. Following Step 124 and the embodiment 400 shown in FIG. 32a, after the monolithic signal lead 138 and the semiconductor package 20 are mounted on the substrate 110, FIG. 33a shows a cross-sectional view that a module molding layer 140 is formed for encapsulating the substrate 110, the monolithic signal lead 138, the semiconductor package 20, as well as a part of the external connecting mechanism 112 coupled to the substrate 110. The module molding layer 140 may be made of insulating materials by any suitable methods, such as molding materials. Then, a grinding process is performed onto the module molding layer 140 by the grinding device 212 for exposing a top portion 1382 of the monolithic signal lead 138 from the module molding layer 140, while a bottom portion 1384 of the monolithic signal lead 138 is still encapsulated inside the module molding layer 140. Accordingly, FIG. 33b shows a cross-sectional view of the embodiment 420 after the optional Step S128.

FIG. 34 illustrates the optional Step S126 of the panel-level method S100 to the embodiment 420 for making another embodiment 430 of the power module 10. As described above, a heat dissipation device (such as the heat sink 150) is attached to the substrate 110 for enhancing dissipation of heat generated from the semiconductor package 20. FIG. 34 shows a cross-sectional view of the embodiment 430.

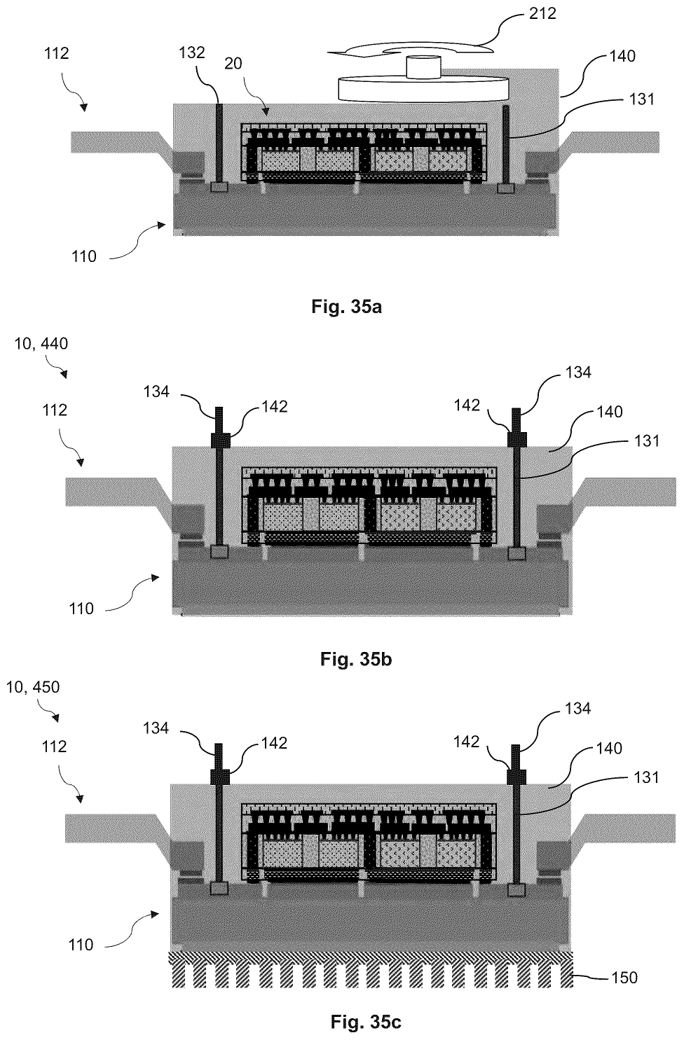

FIGS. 35a & 35b illustrate another optional Step S130 of the panel level method S100 and an embodiment 440 of the power module 10. Instead of mounting the monolithic signal lead 138, FIG. 35a shows a cross-sectional view that multiple first signal leads 131 are mounted and coupled onto the power module 10 around the semiconductor package 20. The first signal leads 131 are made of any electrically materials, such as metals. Preferably, the first signal leads 131 are made of copper (Cu). Similarly, the third electrically conducting joint 124 must be formed between the substrate 110 and the first signal leads 131. In particular, the first signal leads 131 have another lead height greater than the package thickness of the semiconductor package 20. After the module molding layer 140 is formed as described above, a grinding process is performed onto the module molding layer 140 by the grinding device 212 so that a lead top surface 132 of the first signal lead 131 is exposed from the module molding layer 140.

FIG. 35b shows a cross-sectional view that multiple second signal leads 134 are coupled to the multiple first signal leads 131 respectively by any suitable methods, such as a fastener 142 for mechanically coupling the first signal lead 131 and the second signal lead 134 together. For example, the first signal lead 131 and the second signal lead 134 may have internal threads and external threads respectively which match with each other, so that the first signal lead 131 and the second signal lead 134 can be mechanically fixed together. The first signal lead 131 and the second signal lead 134 can be made of any conducting materials such as metals. Preferably, the first signal lead 131 and the second signal lead 134 are made of copper (Cu); and their combination is called a Cu pin accordingly. The first signal lead 131 and the second signal lead 134 are electrically coupled to a gate driver (not shown) which control performance of the power module 10, such as switches between an “ON” status and an “OFF” status for the power inverters. Accordingly, the embodiment 440 is formed for the power module 10 as shown in FIG. 35b.

FIG. 35c illustrates the optional Step S126 of the panel-level method S100 to the embodiment 440 for making another embodiment 450 of the power module 10. As described above, a heat dissipation device (such as the heat sink 150) is attached to the substrate 110 for enhancing dissipation of heat generated from the semiconductor package 20. FIG. 35c shows a cross-sectional view of the embodiment 450. For the embodiments 400 to 450 of the power module 10 described above, the semiconductor package 20 is mounted in a face-up configuration, i.e., the low-side active surface 2022 of the low-side semiconductor die 202 and the high-side active surface 2042 of the high-side semiconductor die 204 face away from the substrate 110. Therefore, the external connection layer 248 at the back build-up layer 220 must be exposed to be in contact with the substrate 110. Then, the semiconductor package 20 in the embodiments 290 and 330 cannot be mounted in the face-up configuration since the external connection layer 248 is completely encapsulated in the external connection dielectric layer 249.

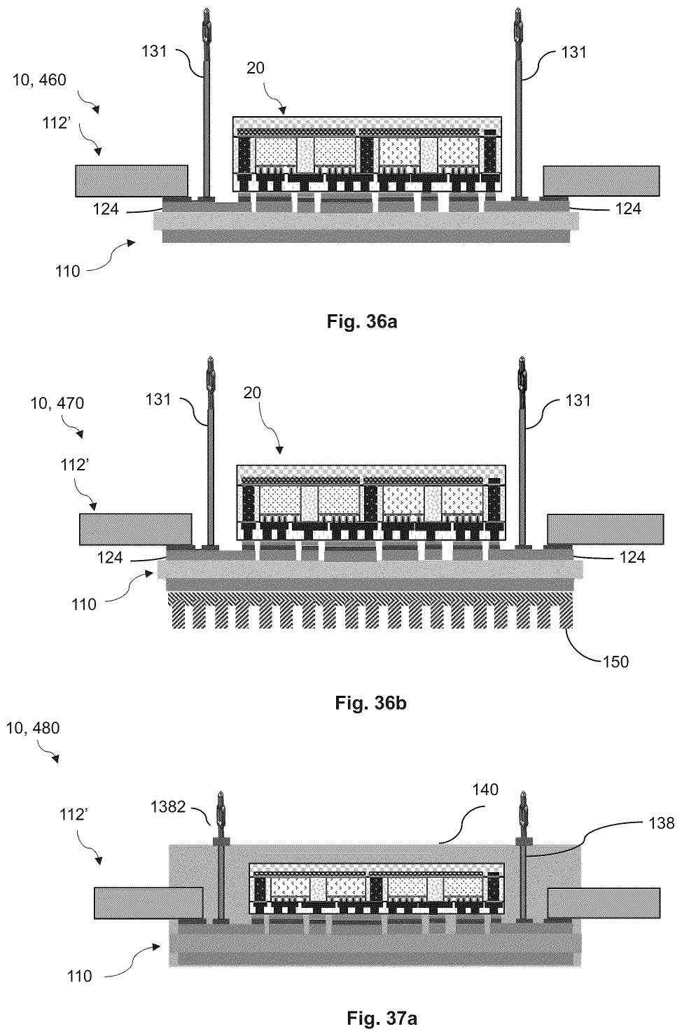

Instead of the face-up configuration, the semiconductor package 20 may be mounted in a face-down configuration, i.e., the low-side active surface 2022 of the low-side semiconductor die 202 and the high-side active surface 2042 of the high-side semiconductor die 204 face to the substrate 110. For example, FIGS. 36a to 38b illustrates other embodiments 460, 470, 480, 490, 500 and 510 of the power module 10 where the embodiment 290 is mounted in the face-down configuration as the semiconductor package 20. Compared with the face-up configuration, the face-down configuration could enhance heat dissipation of the semiconductor package 20 to the substrate 110 since most of the heat are generated by the functional circuitries of the semiconductor dies (such as the low-side semiconductor die 202 and the high-side semiconductor die 204) which are directly in contact with the substrate 110. It is understood that the embodiment 330 of the semiconductor package 20 can also be mounted in the face-up configuration.

FIG. 36a shows a cross-sectional view of the embodiment 460 which corresponds to the embodiment 400 except that the embodiment 290 of the semiconductor package 20 is mounted in the face-down configuration. FIG. 36a also shows another external connecting mechanism 112′ which has only the first part 114 having the substantially flat configuration. It is understood that the embodiment 290 can also be mounted in the external connecting mechanism 112 in the face-down configuration. FIG. 36b shows a cross-sectional view of the embodiment 470 which corresponds to the embodiment 410 that the heat sink 150 is attached to the substrate 110.

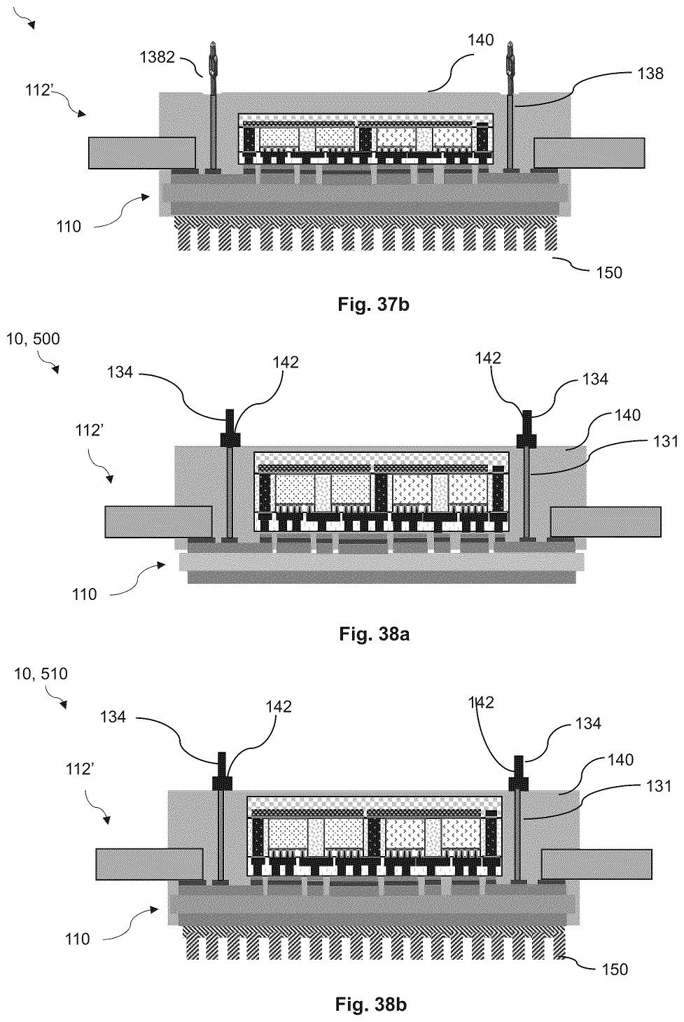

FIG. 37a shows a cross-sectional view of the embodiment 480 which corresponds to the embodiment 420 except that the embodiment 290 of the semiconductor package 20 is mounted in the face-down configuration. FIG. 37b shows a cross-sectional view of the embodiment 490 which corresponds to the embodiment 430 that the heat sink 150 is attached to the substrate 110.

FIG. 38a shows a cross-sectional view of the embodiment 500 which corresponds to the embodiment 440 except that the embodiment 290 of the semiconductor package 20 is mounted in the face-down configuration. FIG. 38b shows a cross-sectional view of the embodiment 510 which corresponds to the embodiment 450 that the heat sink 150 is attached to the substrate 110. It is understood that although not shown, other embodiments of the power modules 100 are also within the present disclosure by mounting other embodiments of the semiconductor package 20 onto the substrate 110, such as the embodiments 280, 310 and 320 (which can also be mounted in the face-up configuration described above).

FIGS. 39a & 39b illustrates another two embodiments 340, 350 of the semiconductor package 20. Following the molded panel 210 (with the back build-up layer 220 and the front-build up layer 230) as shown in FIG. 18 (except that the back RDL layer 224 is completely encapsulated inside the back dielectric layer 226), the first thickness of the first front dielectric layer 236 is much smaller here than what has described above (such as 100 micrometers μm)) if the first front dielectric layer 236 is made of solder mask materials or photoimageable dielectric materials. In an embodiment, the first thickness is around 10 micrometers(μm) as shown in FIG. 39a. Then, the grooves 238 are made as shown in FIG. 19 by the photolithography or photoimageable technologies; and the first front RDL 234 is exposed from the first front dielectric layer 236. Accordingly, the grooves 238 have a depth substantially equal to the first thickness of the first front dielectric layer 236, such as around 10 micrometers (μm). The grooves 238 are not filled in the subsequent processes as described above, including Step S116 where the molded panel 210 is released from the second carrier 106a and the second heat and release layer 108; and Step S120 where the molded panel 210 is singulated into the embodiment 340 of the semiconductor package 20. FIG. 39a shows a cross-sectional view of the embodiment 340 finally obtained with the grooves 238 still kept unfilled. Similarly, the grooves 238 are not filled in the subsequent processes for the embodiment 350. The embodiment 350 differs from the embodiment 340 in that it does not have the back build-up layer 220; and accordingly, the external connection layer 248 is directly formed on the back surface 2104 of the molded panel 210. FIG. 39b shows a cross-sectional view of the embodiment 350 finally obtained with the grooves 238 still kept unfilled.

FIGS. 40a & 40b illustrates another embodiment of S124 of the panel-level method S100 with the embodiments 340 of the semiconductor package 20 for making an embodiment 520 of the power module 10. FIG. 40a shows a cross-sectional view that the embodiment 340 is mounted in the face-down configuration and coupled to the substrate 110 with the grooves 238 unfilled. FIG. 40b shows a cross-sectional view that during the formation of the second electrically conducting joint 122 between the substrate 110 and the embodiment 340 of the semiconductor package 20, the electrically conducting adhesives (such as the epoxy-silver pastes) would enter and fill in the grooves 238 in the process of silver sintering. In particular, the electrically conducting adhesives (such as the epoxy-silver pastes) have an adhesive thickness more than the depth of the grooves 238, such as in a range of 10 to 20 micrometers (μm), or more particularly around 14 micrometers (μm) when the first thickness of the first front dielectric layer 236 is less than or around 10 micrometers (μm). Accordingly, the filled grooves 240 are electrically coupled to the first front RDL 234 of the front-build up layer 230 in the embodiment 340 of the semiconductor package 20. Instead of the electrically conducting adhesives (such as the epoxy-silver pastes) and the process of silver sintering, the grooves 238 may be filled with solder materials (such as solder balls) in a process of solder reflowing when the solder materials have a solder thickness more than the depth of the grooves 238, such as in a range of 10 to 20 micrometers (μm), or more particularly around 14 micrometers (μm) when the first thickness of the first front dielectric layer 236 is less than or around 10 micrometers (μm). Similarly, the solder materials would enter and fill in the grooves 238 in the process of solder reflowing. It is understood the embodiment 350 with the grooves 238 kept unfilled can also be mounted in the face-down configuration and the grooves 238 are filled during the formation of the second electrically conducting joint 122 as described above for the embodiment 340 of the semiconductor package 20.

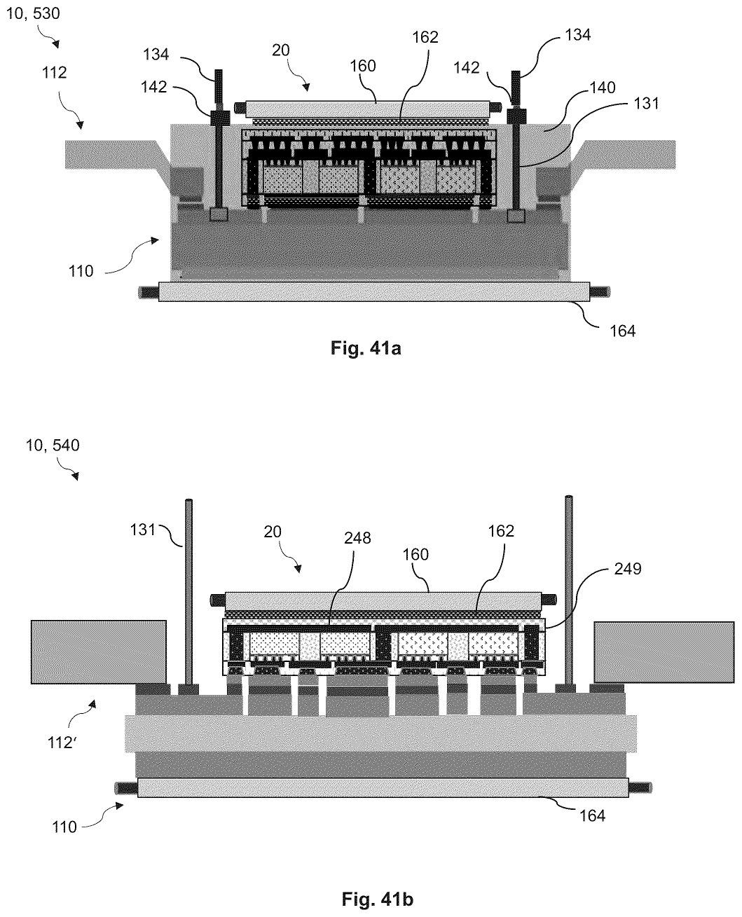

FIGS. 41a & 41b illustrates other embodiments 530, 540 of the power module 10 with a liquid cooling system as another embodiment of the heat dissipation device. FIG. 41a shows a cross-sectional view of the embodiment 530 of the power module 10 where the semiconductor package 20 is mounted onto the substrate 110 in the face-up configuration, while a first liquid cooling system 160 is attached to the module molding layer 140 either directly or through an intermediate component 162 (such as a heat dissipation metal layer) as shown in FIG. 41a. Meanwhile, a second liquid cooling system 164 may be attached to the bottom surface 1110 of the substrate 110, in replacement of the heat sink 150 for dissipating heat generated by the semiconductor package 20. FIG. 41b show a cross-sectional view that the semiconductor package 20 is mounted onto the substrate 110 in the face-down configuration. Similarly, the first liquid cooling system 160 is attached to the external connection dielectric layer 249 either directly or through the intermediate component 162 (such as a heat dissipation metal layer) as shown in FIG. 41b. Meanwhile, the second liquid cooling systems 164 may be also attached to the bottom surface 1110 of the substrate 110. The first and second liquid cooling systems 160, 164 may be a liquid-to-liquid type, a closed-loop dry system type, a closed-loop dry system with trim cooling type, an open-loop evaporative system type, a closed-loop evaporative system type, a chilled water system type, or any combination thereof. But it is understood that the heat sink 150 may be still kept at the bottom surface 1110 of the substrate 110, while the first liquid cooling system 160 is attached to the module molding layer 140 (FIG. 41a) or the external connection dielectric layer 249 of the semiconductor package 20 (FIG. 41b).

In the application, unless specified otherwise, the terms “comprising”, “comprise”, and grammatical variants thereof, intended to represent “open” or “inclusive” language such that they include recited elements but also permit inclusion of additional, non-explicitly recited elements.

As used herein, the term “about”, in the context of concentrations of components of the formulations, typically means +/−5% of the stated value, more typically +/−4% of the stated value, more typically +/−3% of the stated value, more typically, +/−2% of the stated value, even more typically +/−1% of the stated value, and even more typically +/−0.5% of the stated value.

Throughout this disclosure, certain embodiments may be disclosed in a range format. The description in range format is merely for convenience and brevity and should not be construed as an inflexible limitation on the scope of the disclosed ranges. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1to 4, from 1 to 5, from 2 to 4, from 2 to 6, from 3 to 6 etc., as well as individual numbers within that range, for example, 1, 2, 3, 4, 5, and 6. This applies regardless of the breadth of the range.

It will be apparent that various other modifications and adaptations of the application will be apparent to the person skilled in the art after reading the foregoing disclosure without departing from the spirit and scope of the application and it is intended that all such modifications and adaptations come within the scope of the appended claims.

1. A semiconductor package for a power module, comprising:
at least one high-side semiconductor die having a high-side active surface and a high-side inactive surface;
at least one low-side semiconductor die having a low-side active surface and a low-side inactive surface;
a plurality of vertical structures surrounding the at least one high-side semiconductor die and at least one low-side semiconductor die, wherein each of the vertical structure has a front surface aligned with the high-side active surface and low-side active surface and a back surface aligned with the high-side inactive surface and the low-side inactive surface;
a molding layer encapsulating the at least one high-side semiconductor die and at least one low-side semiconductor die and the plurality of vertical structures;
a front build-layer coupled to the at least one high-side semiconductor die at the high-side active surface, the at least one low-side semiconductor die at the low-side active surface, and the vertical structure at the front surface;
a back build-up layer coupled to the at least one high-side semiconductor die at the high-side inactive surface, the at least one low-side semiconductor die at the low-side inactive surface, and the vertical structure at the back surface; and
an external connection layer coupled to the back build-up layer.

2. The semiconductor package of claim 1, wherein
the vertical structure comprises multiple copper (Cu) columns, multiple Molded Interconnect substrate (MIS) units, multiple Molded Via substrate (MVS) units, or any combination thereof.

3. The semiconductor package of claim 1, wherein
the high-side active surface of the high-side semiconductor die, the low-side active surface of the low-side semiconductor die and the front surface of the vertical structure are exposed from a first molding surface; and
the high-side inactive surface of the high-side semiconductor die, the low-side inactive surface of the low-side semiconductor die and the back surface of the vertical structure are exposed from a second molding surface of the molding layer.

4. The semiconductor package of claim 1, wherein the front build-layer further comprises
a front redistribution layer (RDL) electrically coupled to the high-side active surface of the high-side semiconductor die, the low-side active surface of the low-side semiconductor die and the front surface of the vertical structure; and
a front dielectric layer encapsulating the front redistribution layer (RDL).

5. The semiconductor package of claim 1, wherein the back build-up layer further comprises:
a back redistribution layer (RDL) electrically coupled to the back surface of the vertical structure; and
a back dielectric layer encapsulating the back redistribution layer (RDL).

6. The semiconductor package of claim 1, wherein
the at least one high-side semiconductor die comprises 8 silicon carbide (SiC) high-side metal-oxide-semiconductor field-effect transistors (MOSFETs) electrically coupled to a high-side gate; and
the at least one low-side semiconductor die comprises 8 silicon carbide (SiC) low-side metal-oxide-semiconductor field-effect transistors (MOSFETs) electrically coupled to a low-side gate.

7. The semiconductor package of claim 6, wherein the external connection layer comprises
a low-side external connection layer in contact with the inactive surface of the at least one low-side semiconductor die for functioning as a low-side drain;
a high-side external connection layer in contact with the inactive surface of the at least one high-side semiconductor die for functioning as a high-side drain;
a first external connection layer in contact with a plurality of first copper columns for functioning as a low-side source;
a second external connection layer in contact with a second copper column for functioning as a low-side gate;
a third external connection layer in contact with a plurality of third copper columns for functioning as a high-side source; and
a fourth external connection layer in contact with a fourth copper column for functioning as a high-side gate.

8. A power module, comprising:
a semiconductor package comprising at least one low-side semiconductor die and at least one high-side semiconductor die;
a copper substrate on which the semiconductor package is mounted on, wherein functional circuitries of the at least one low-side semiconductor die and at least one high-side semiconductor die are led out to the substrate;
an external connecting mechanism coupled to the substrate for electrically leading out the power module; and
at least one signal lead mounted on the substrate.

9. The power module of claim 8, wherein
the at least one signal lead comprises a monolithic signal lead or a combination of a first signal lead and a second signal lead coupled together.

10. The power module of claim 9, further comprising:
a module molding layer for encapsulating the at least one signal lead and the semiconductor package, wherein the at least one signal lead is partially exposed from the module molding layer.

11. The power module of claim 8, wherein
the external connecting structure comprises a DC positive Cu clip, a DC negative Cu clip and an AC Cu clip.

12. The power module of claim 8, further comprising
the semiconductor package is mounted in either a face-up configuration or a face-down configuration.

13. The power module of claim 8, further comprising:
a heat dissipation device coupled to the substrate.

14. A method of making a power module, comprising:
making a semiconductor package configured for the power module, wherein the semiconductor package comprises at least one low-side semiconductor die and at least one high-side semiconductor die;
mounting the semiconductor package onto a copper substrate, wherein functional circuitries of the at least one low-side semiconductor die and at least one high-side semiconductor die are led out to the substrate;
coupling an external connecting mechanism to the substrate; and
mounting at least one signal lead onto the substrate.

15. The method of claim 14, wherein the making the semiconductor package further comprising:
bonding the at least one high-side semiconductor die and the at least one low-side semiconductor die onto a first carrier;
bonding a plurality of vertical structures onto the first carrier;
forming a molding layer encapsulating the at least one high-side semiconductor die, the at least one low-side semiconductor die and the plurality of vertical structures for forming a molded panel;
forming a front build-layer coupled to the at least one high-side semiconductor die, the at least one low-side semiconductor die and the vertical structure;
forming a back build-up layer coupled to the at least one high-side semiconductor die, the at least one low-side semiconductor die and the vertical structure;
forming an external connection layer coupled to the back build-up layer; and
singulating the molded panel, the front build-up layer, the back build-up layer and the external connection layer into the individual semiconductor packages.

16. The method of claim 15, further comprising:
filling pre-vias of the at least one high-side semiconductor die and the at least one low-side semiconductor die into filled vias, wherein the filled vias are coupled to the front build-up layer.

17. The method of claim 15, further comprising:
singulating the molded panel, the front build-up layer and the back build-up layer into multiple sub-panels before forming the external connection layer; and
singulating the sub-panel into the individual semiconductor packages after forming the external connection layer.

18. The method of claim 15, further comprising
removing a first top portion of the molding layer for exposing a back surface of the vertical structure; and
removing a second top portion of the molding layer for exposing inactive surfaces of the at least one high-side semiconductor die and the at least one low-side semiconductor die.

19. The method of claim 14, further comprising:
forming a module molding layer for encapsulating the semiconductor package and partially the at least one signal lead.

20. The method of claim 14, further comprising:
attaching a heat dissipation device to the substrate.
